(19) United States
(12) Patent Application Publication
(10) Pub. No.: US 2026/0107628 A1
(43) Pub. Date: Apr. 16, 2026

(54) SYNTHESIS METHOD FOR HEXAPHENYLBENZENE-BASED ORGANIC SMALL MOLECULES AND APPLICATION IN ELECTROLUMINESCENT DEVICES

(71) Applicant: Tianjin University, Tianjin (CN)

(72) Inventors: Hongli LIU, Tianjin (CN); Yuhong WANG, Tianjin (CN); Taixin ZHOU, Tianjin (CN); Shirong WANG, Tianjin (CN); Xianggao LI, Tianjin (CN)

(73) Assignee: Tianjin University, Tianjin (CN)

(21) Appl. No.: 19/420,694

(22) Filed: Dec. 15, 2025

(30) Foreign Application Priority Data
Feb. 11, 2025 (CN) 202510150128.4

(51) Int. Cl. H10K 50/115; C09K 11/06; H10K 85/60

(52) U.S. Cl. CPC H10K 50/115; C09K 11/06; H10K 85/6572; C09K 2211/1007

(57) ABSTRACT

The present disclosure belongs to the field of photoelectric material technology, especially relates to a synthesis method for hexaphenylbenzene-based organic small molecules and the application in electroluminescent devices. The present disclosure effectively improves hole injection through the regular stacking of hexaphenylbenzene molecules and strong π electron delocalization. The synthesis method in the present disclosure is simple and environmentally friendly. The obtained hexaphenylbenzene-based organic small molecule photoelectric material has good optical properties and can be used in the fields of sensitized solar cells, organic light-emitting diodes, quantum dot light-emitting diodes, ion detection and ion probes, organic field effect transistors, and organic semiconductor materials. The efficiency of devices doped with such molecules is greatly improved compared with the undoped standard, and the efficiency before and after doping can be significantly improved from an undoped EQE=9.57% to 15.29%.

### TECHNICAL FIELD

The present disclosure belongs to the field of photoelectric material technology, especially relates to a synthesis method for hexaphenylbenzene-based organic small molecules and an application in electroluminescent devices.

### BACKGROUND

Light-emitting diodes (LEDs) have garnered increasing attention in the contemporary era, characterized by a growing emphasis on environmental protection and energy conservation, owing to their advantages such as low energy consumption, minimal heat generation, and long lifespan. They have progressively replaced traditional lighting technologies and emerged as a new generation of light sources. As the core component of LEDs, luminescent materials play a crucial role in determining their performance. Phosphors, as the first generation of LED luminescent materials, have been widely adopted in LED lighting and display applications. However, they suffer from drawbacks such as significant light attenuation, poor particle uniformity, and limited service life, which severely restrict the development of phosphor-based LEDs. Organic light-emitting diodes (OLEDs) represent a research focus in the new generation of LED technology. Nevertheless, challenges remain in their encapsulation technology and operational longevity. Quantum dots (QDs), as a novel class of luminescent materials, offer advantages including high color purity, high luminescent quantum efficiency, tunable emission wavelengths, and long service life. They have thus become a prominent research topic in the field of new LED luminescent materials. Consequently, quantum dot light-emitting diodes (QLEDs), which utilize QDs as the emitting layer, have emerged as a major direction in next-generation LED research and hold broad application prospects in lighting and flat-panel displays.

In recent years, significant improvements in QLED performance have been achieved through advances in the synthesis of quantum dot materials and optimization of device structures. However, the issue of imbalanced carrier injection—stemming from the inherent ease of electron injection and difficulty of hole injection—has not been adequately resolved. This problem is particularly pronounced in short-wavelength QLEDs, where the larger ionization potential further impedes hole injection, exacerbating carrier imbalance. This remains one of the primary factors limiting the performance of short-wavelength QLED devices. Currently, commonly used hole transport materials (HTMs), such as poly[(9,9-dioctylfluorenyl-2,7-diyl)-alt-(4,4′-(N-(4-butylphenyl))](TFB), poly(N,N′-bis(3-methylphenyl)-N,N′-bis(phenyl)benzidine) (poly-TPD), and poly(N-vinylcarbazole) (PVK), exhibit hole mobilities in the range of approximately 10⁻⁶ to 10⁻³ cm²·V⁻¹·s⁻¹ which is considerably lower than that of electron transport materials (typically around 10⁻³ to 10⁻² cm²·V⁻¹·s⁻¹).

### SUMMARY

The purpose of this present disclosure is to provide a synthesis method for hexaphenylbenzene-based organic small molecules and an application in electroluminescent devices, mainly based on the application, in order to solve the technical problem of serious non-radiative recombination caused by unbalanced charge injection.

In order to solve the above technical problems, the specific technical scheme of the present disclosure is as follows:

In some embodiments of this application, a synthetic method for hexaphenylbenzene-based organic small molecules is provided, which have one or more of the chemical structures shown in Formula I or Formula II:

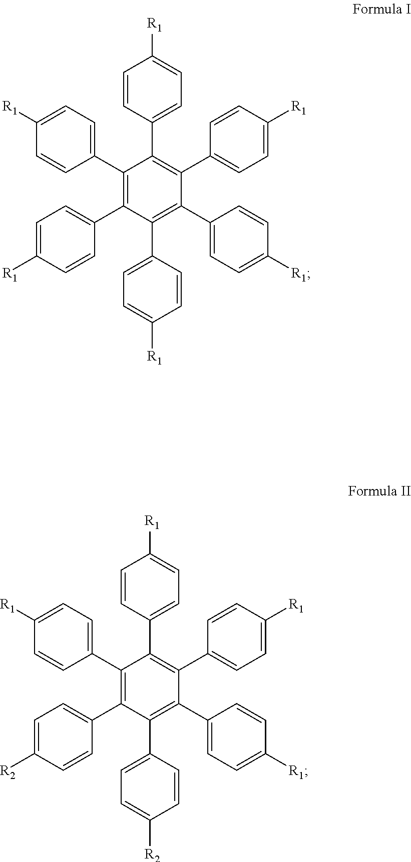

where R₁ and R₂ in Formula I or Formula II include:

One or several combinations of

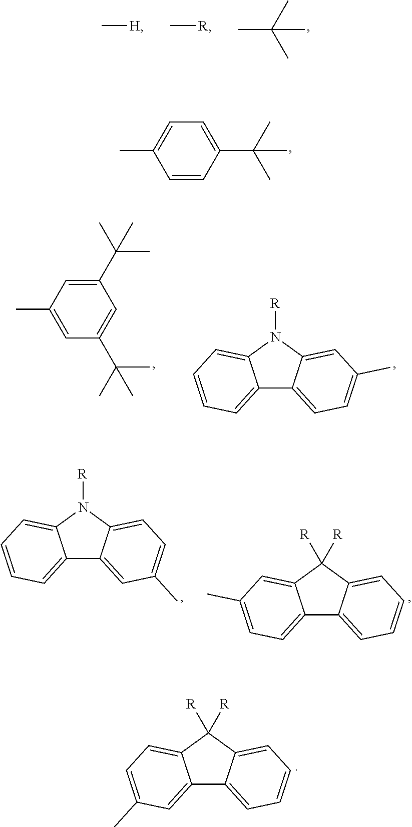

In some embodiments of this application, —R is a long-chain alkyl or long-chain alkoxy group and consists of the following 24 molecules:

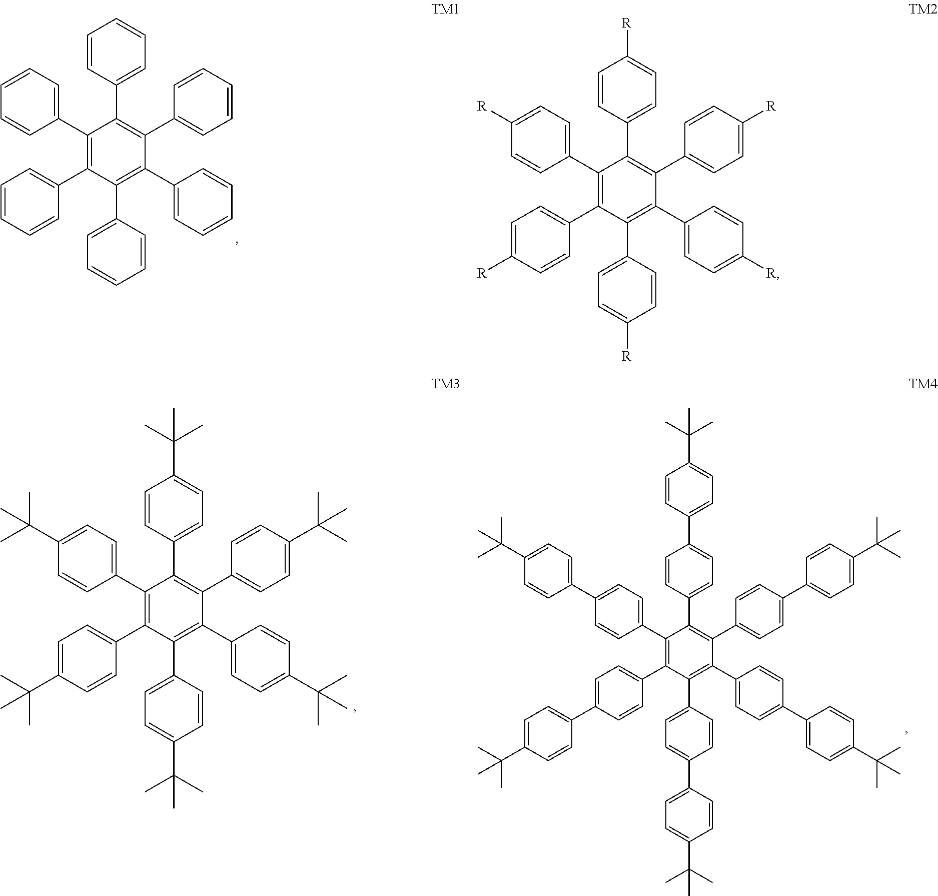

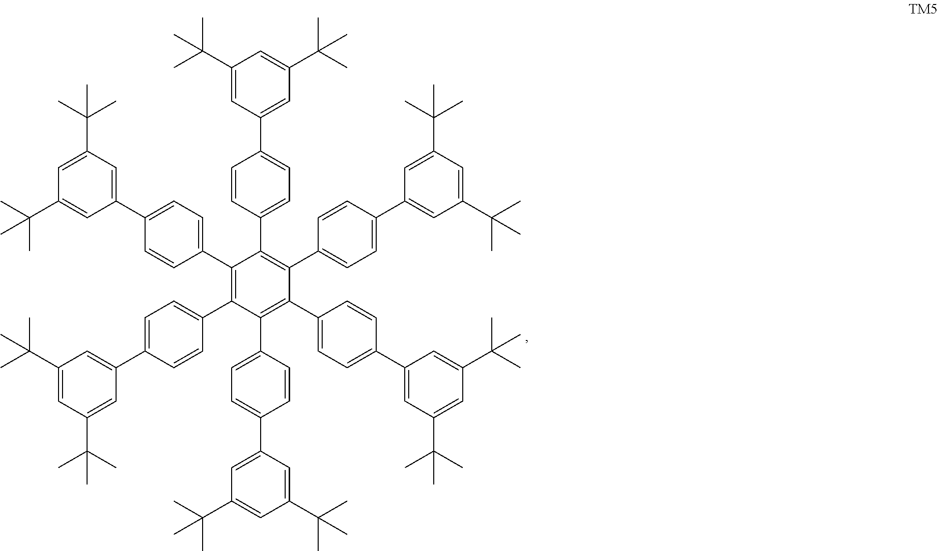 [SMILES: CC(C)(C)c1cc(-c2ccc(-c3c(-c4ccc(-c5cc(C(C)(C)C)cc(C(C)(C)C)c5)cc4)c(-c4ccc(-c5cc(C(C)(C)C)cc(C(C)(C)C)c5)cc4)c(-c4ccc(-c5cc(C(C)(C)C)cc(C(C)(C)C)c5)cc4)c(-c4ccc(-c5cc(C(C)(C)C)cc(C(C)(C)C)c5)cc4)c3-c3ccc(-c4cc(C(C)(C)C)cc(C(C)(C)C)c4)cc3)cc2)cc(C(C)(C)C)c1]

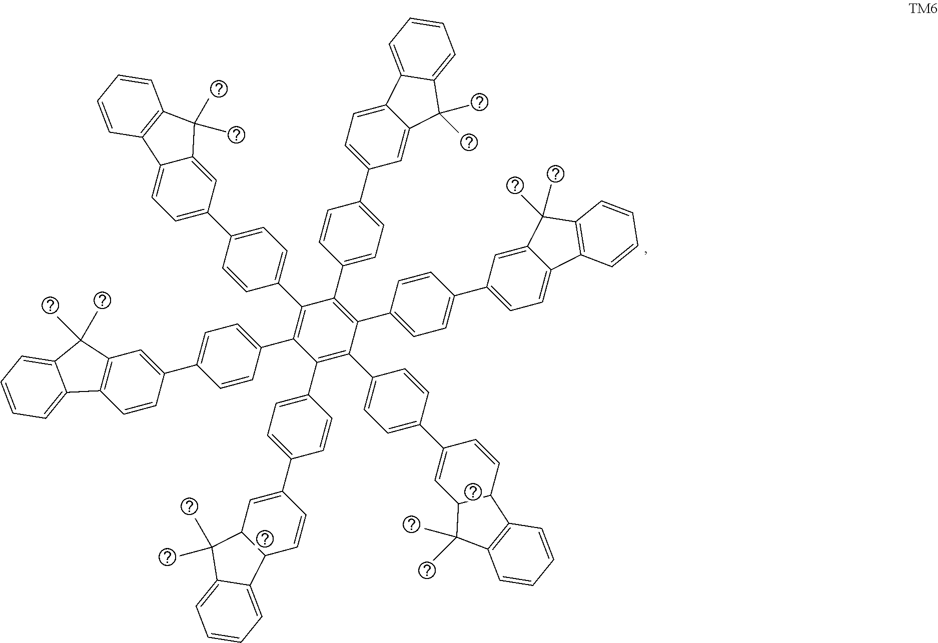 [SMILES: CC1(C)c2ccccc2-c2ccc(-c3ccc(-c4c(-c5ccc(C6=CC7C(C=C6)c6ccccc6C7(C)C)cc5)c(-c5ccc(C6=CC7C(C=C6)c6ccccc6C7(C)C)cc5)c(-c5ccc(-c6ccc7c(c6)C(C)(C)c6ccccc6-7)cc5)c(-c5ccc(-c6ccc7c(c6)C(C)(C)c6ccccc6-7)cc5)c4-c4ccc(-c5ccc6c(c5)C(C)(C)c5ccccc5-6)cc4)cc3)cc21]

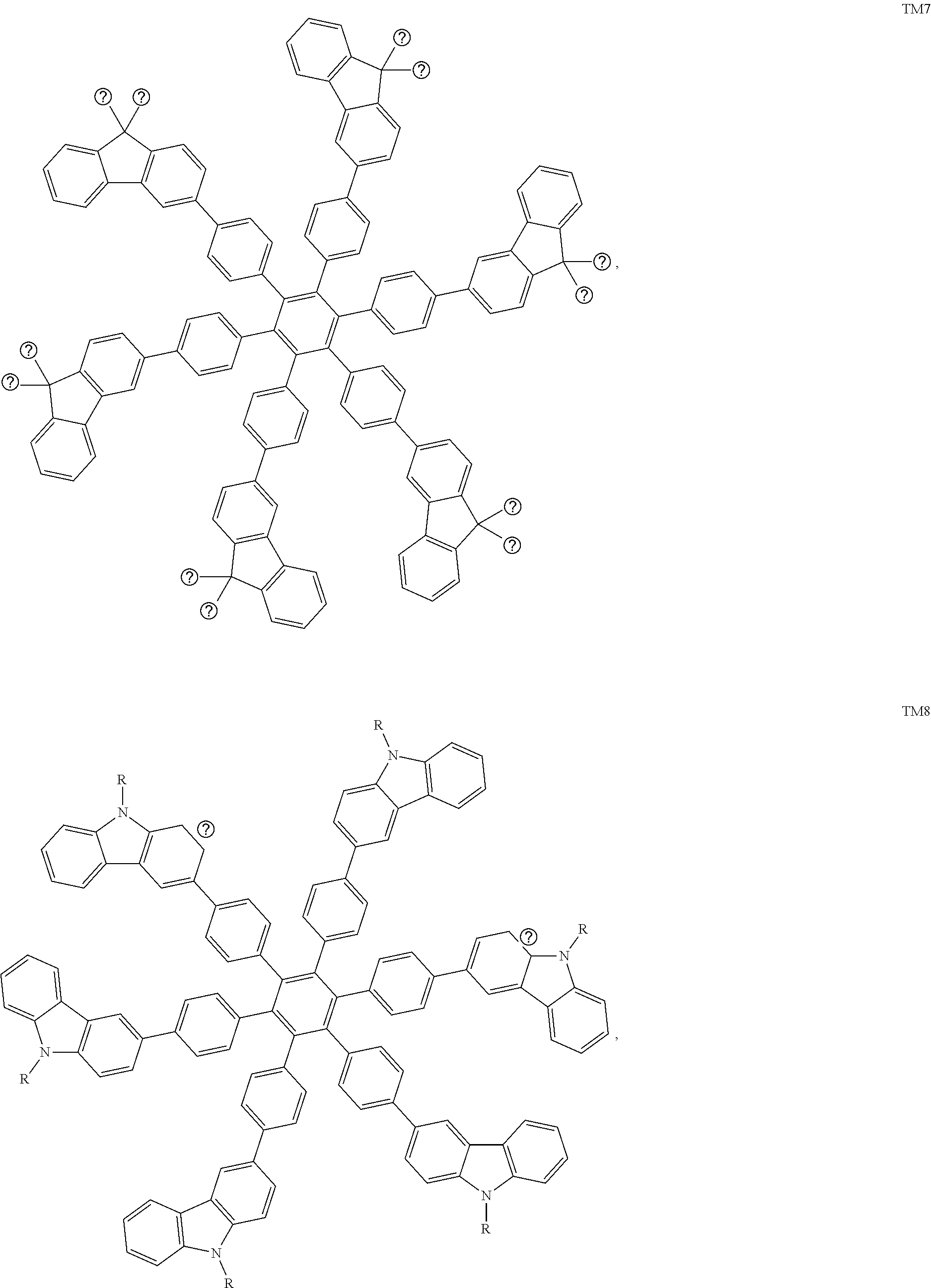

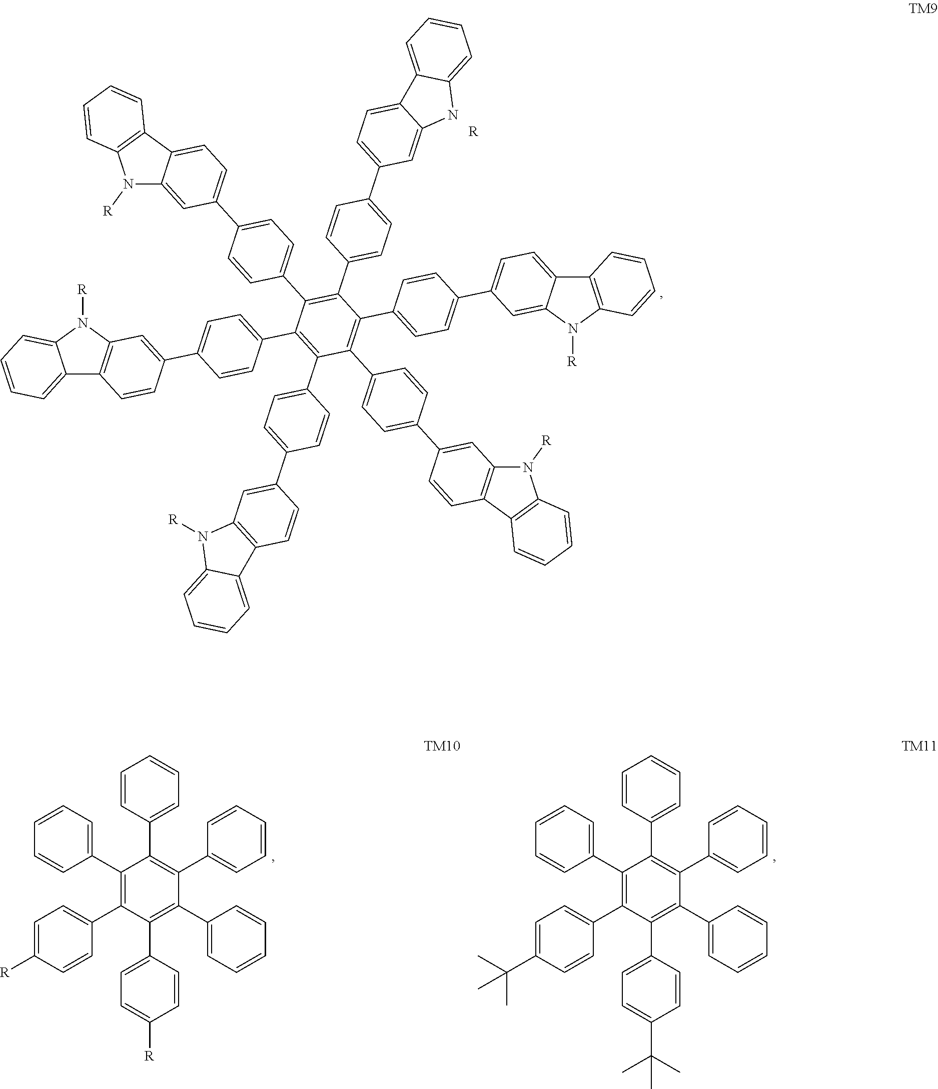

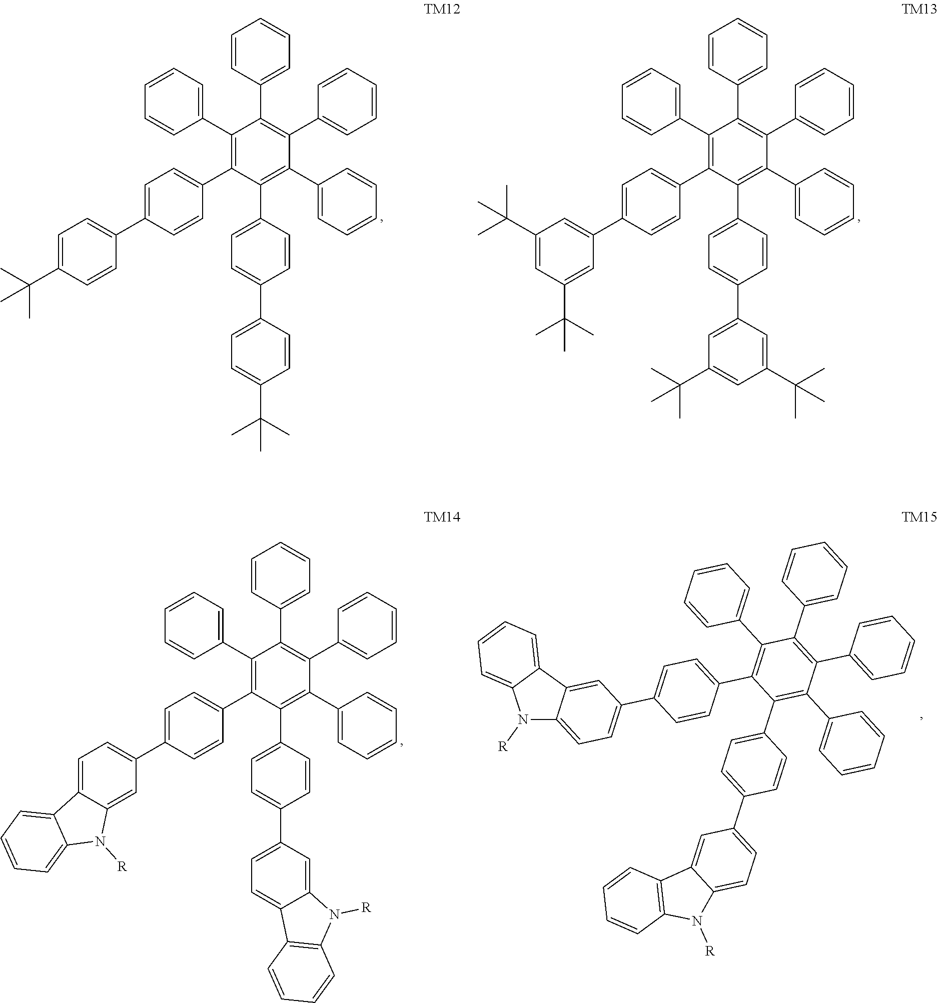

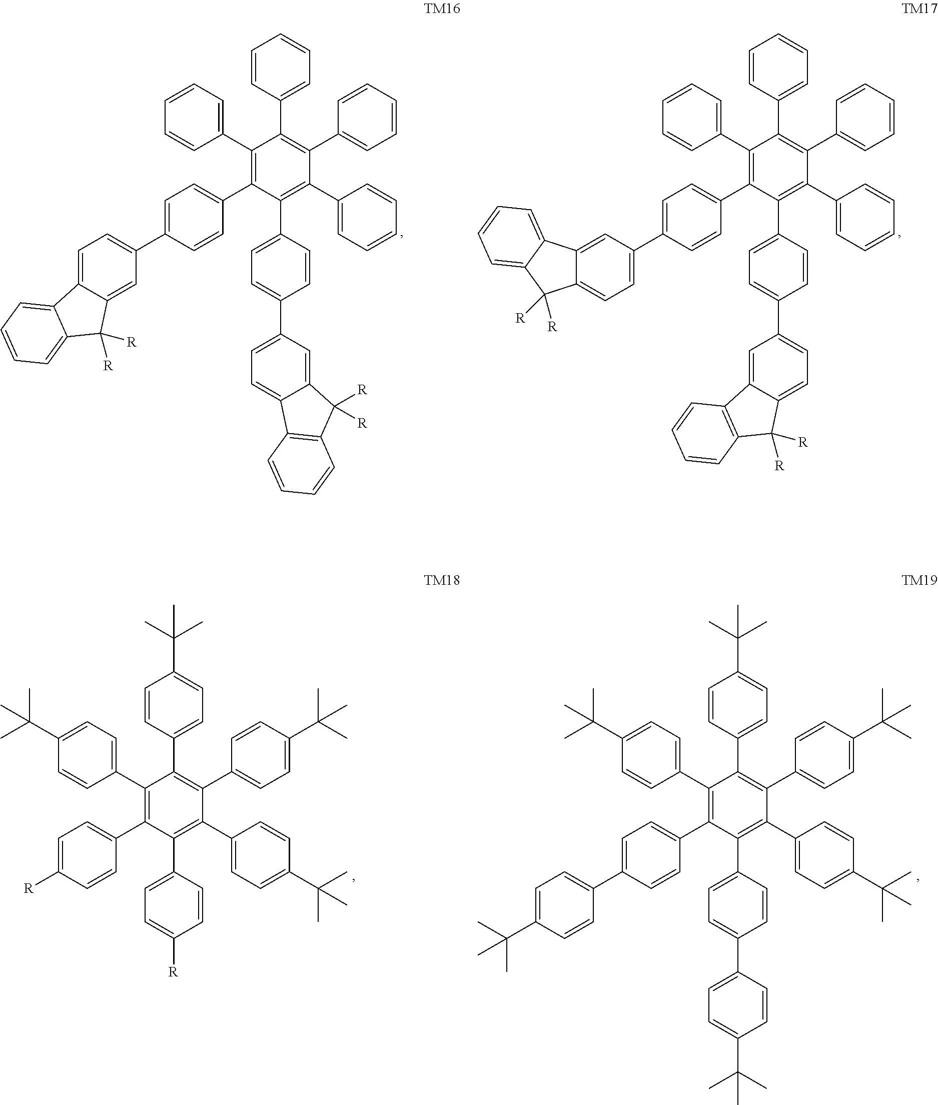

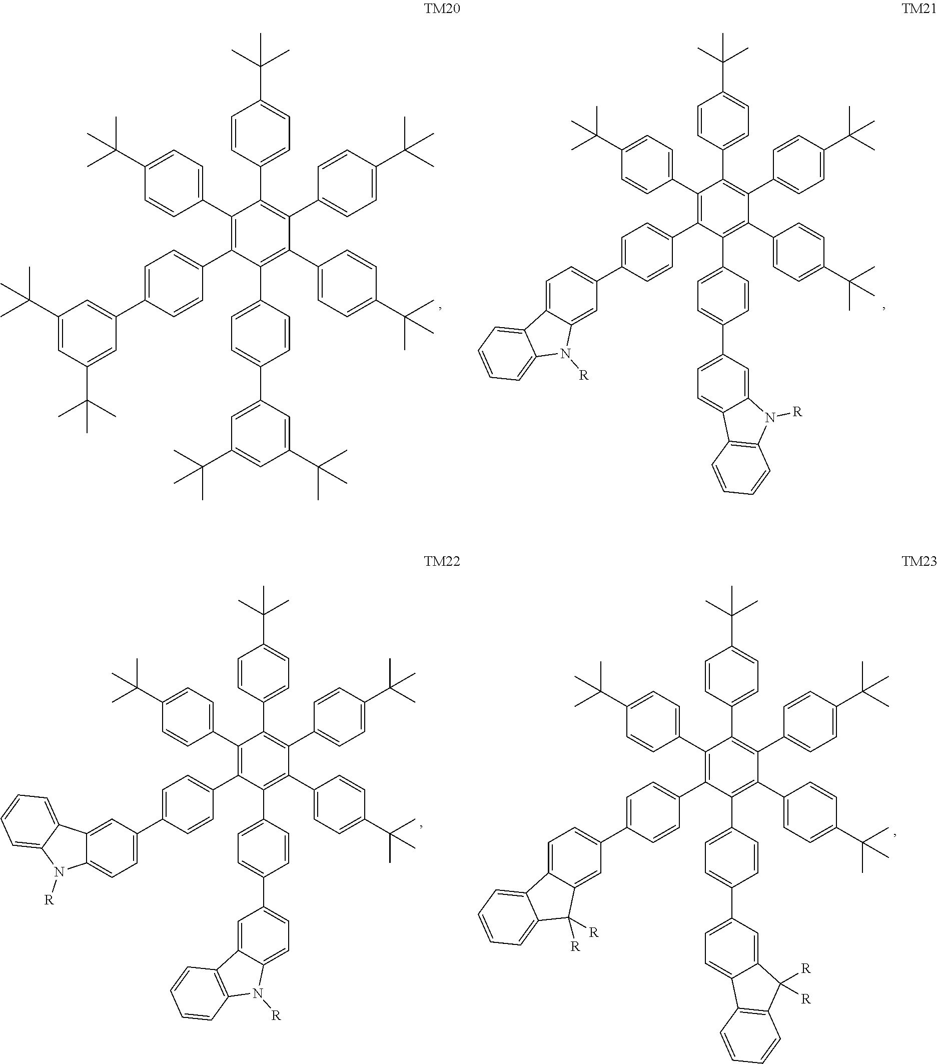

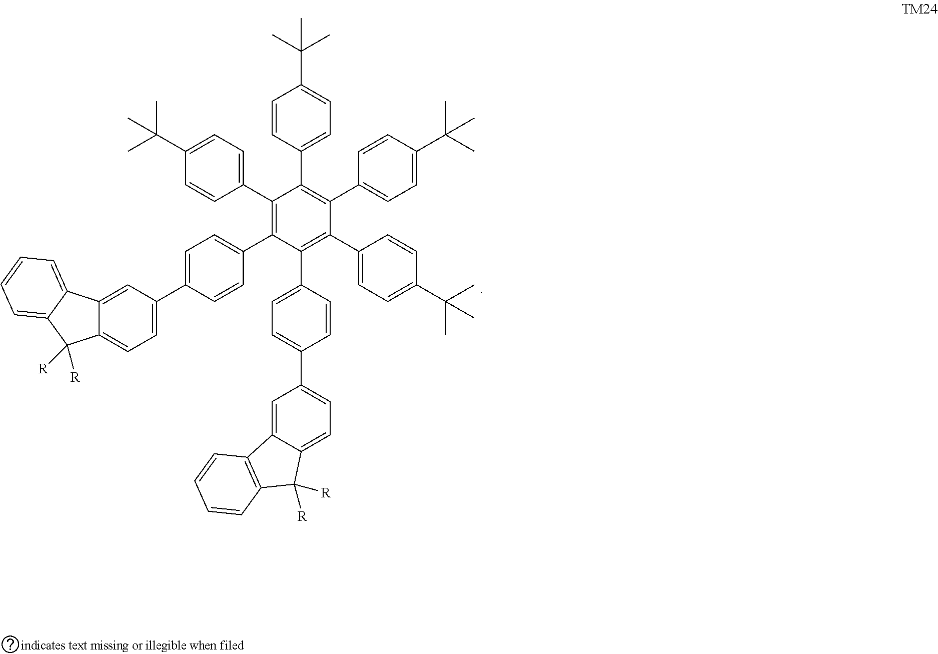

In some embodiments of this application, for simple side chains of less than or equal to five carbons, the synthesis method of Formula I includes the following steps:
Step 1) Under a protection of inert gas, obtaining a first intermediate by a reaction of iodobenzene derivatives and phenylacetylene derivatives with a molar ratio of 1:(1-1.5) as raw materials, triethylamine as a solvent, cuprous iodide, and bis(triphenylphosphine) palladium chloride as catalysts at room temperature for 10-15 h.
Step 2) Under the protection of inert gas, using the first intermediate as the raw material, 1,4-dioxane as a solvent, and dicobalt octacarbonyl as a catalyst; performing a reaction at 100-130° C. for 8-16 h to obtain a second intermediate, namely hexaphenylbenzene-based organic small molecules in Formula I.

In some embodiments of this application, for a complex side chain of more than five carbons, a synthesis method for Formula I includes the following steps:
Step 1) Under the protection of inert gas, using p-bis(4-bromophenyl)alkyne as a raw material, 1,4-dioxane as a solvent, and dicobalt octacarbonyl as a catalyst, performing a reaction at 100-130° C. for 8-16 h to obtain a third intermediate;
Step 2) Under the protection of inert gas, using the third intermediate with a molar ratio of 1:(6-12) and boric acid or boron ester of a required side chain as raw materials, toluene/tetrahydrofuran as a solvent, tetratriphenylphosphine palladium as a catalyst, tetraethylammonium hydroxide as a base, and reacting at 70-120° C. for 12-36 h to obtain a fourth intermediate, namely hexaphenylbenzene-based organic small molecules in Formula I.

In some embodiments of this application, the synthesis method for hexaphenylbenzene-based organic small molecules in Formula II includes the following steps:
Step 1) Under the protection of inert gas, using diphenylethanedione and 1,3-diphenylacetone or 1,2-bis(4-(tert-butyl)phenyl) ethane-1,2-dione and 1,3-bis(4-(tert-butyl)phenyl) propan-2-one with a molar ratio of 1:1 as raw materials, tert-butanol as a solvent, potassium tert-butanol as a base, and reacting at 90-110° C. for 0.5-1 h to obtain a fifth intermediate.
Step 2) Under the protection of inert gas, using p-bis(4-bromophenyl)alkyne with a molar ratio of 1:2-2.5 and the boric acid or boron ester of a required side chain as raw materials, toluene as a solvent, tetratriphenylphosphine palladium as a catalyst, tetraethylammonium hydroxide as a base, and reacting at 90-110° C. for 10-16 h to obtain a sixth intermediate.
Step 3) Under the protection of inert gas, using the fifth and sixth intermediates with a molar ratio of 1:1 as raw materials, diphenyl ether as a solvent, and performing a reaction at 200-260° C. for 20-24 h to obtain a seventh intermediate, namely the hexaphenylbenzene-based organic small molecules in Formula II.

In some embodiments of this application, an electroluminescent device is disclosed, including a cathode, an anode, and a functional layer between a cathode and an anode; the functional layer contains any of the above-mentioned hexaphenylbenzene-based organic small molecules.

In some embodiments of this application, the specific experimental steps of preparing QLED devices by doping hexaphenylbenzene-based organic small molecules in hole transport materials are as follows:

Common QLED device structures include ITO/HIL/HTL/EML/ETL/AL.

Firstly, the ITO substrate is pretreated, including solvent cleaning and oxygen plasma cleaning. Solvent cleaning is to ultrasonically clean the etched ITO substrate with cleaning agent, deionized water, deionized water, recycled ethanol, and anhydrous ethanol for 20-30 min, respectively; the beaker containing the ITO substrate and anhydrous ethanol solution is placed on a heating stage and the temperature is set to 120-150° C., when the anhydrous ethanol is slightly boiled, the surface solvent is blown off with a nitrogen gas flow. The oxygen plasma cleaning instrument is used for cleaning for 10 min.
(1) The PEDOT: PSS solution is spin-coated on the surface of the pretreated ITO substrate at a speed of 2000-4000 rpm for 30 s, and heated in air at 100-150° C. for 15-30 min to form a hole injection layer (HIL) on the surface of the ITO substrate.
(2) 8-14 mg/ml of PVK solution and 5-10 mg/ml of the above-mentioned hexaphenylbenzene organic molecular solution are configured, the solvent can be chlorobenzene or toluene, and other good solvents. The hexaphenylbenzene organic molecular solution is doped into the PVK solution with 1-30% VOL, and fully shaken and mixed evenly. The hole transport layer (HTL) solution is spin-coated on the HIL film at a speed of 2000-4000 rpm for 30 s, and heated at 100-150° C. for 15-30 min in air. After recovering to room temperature, the film at the electrode required for the test is erased, and a hole transport layer (HTL) is formed on the surface of the hole injection layer.
(3) The film obtained in (2) is transferred to a glove box of inert gas, and the emitting layer quantum dots (QD) n-octane/toluene solution is spin-coated at a speed of 2000-4000 rpm for 30 s. The solution is heated at 80-100° C. for 5-10 min in a nitrogen atmosphere to form an emitting layer (EML) on the surface of the hole transport layer.
(4) The film obtained in (3) is spin-coated with an electron transport layer (ETL) of 15-25 mg/ml ZnO or ZnMgO ethanol solution for 30 s at a rotation speed of 2000-4000 rpm, and heated at 80-100° C. in a nitrogen atmosphere for 15-30 min. After recovering to room temperature, the film at the electrode required for the test is erased, and an electron transport layer (ETL) is formed on the surface of the emitting layer.
(5) The spin-coated ITO substrate obtained by (4) is placed on the mask and placed in the vacuum evaporation chamber. The metal cathode is deposited at a rate of 8-10 Å/s at a vacuum of less than 6×10⁻⁴ Pa to obtain a QLED device.

Compared with the existing technology, the beneficial effect of the present disclosure is that the hole injection is effectively improved by the regular stacking of hexaphenylbenzene molecules and the strong π electron delocalization, so that the efficiency of the device doped with this kind of molecule is greatly improved compared with the undoped contrast device. For the first time, this kind of molecule is applied to the QLED device, and the efficiency before and after doping can be significantly improved from the contrast EQE=9.57% to 15.29%.

### BRIEF DESCRIPTION OF THE DRAWINGS

By reading the detailed description of the preferred implementation method below, various other advantages and benefits will become clear to the general technical personnel in this field. The diagram is only used for the purpose of showing the preferred embodiment, and is fnot considered to be a limitation to the present disclosure. Also, the same reference symbols are used to represent the same parts throughout the drawings. In the attached figures:

FIG. 1 is a schematic diagram of the PVK film-water contact angle of 90.63° provided by the embodiment of the present disclosure;

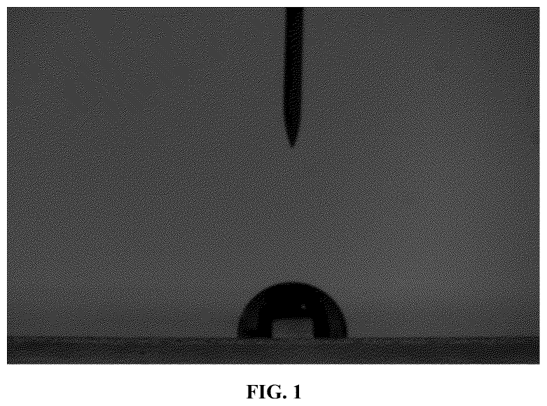

FIG. 2 is a schematic diagram of the PVK film-n-octane contact angle of 9.83° provided by the embodiment of the present disclosure;

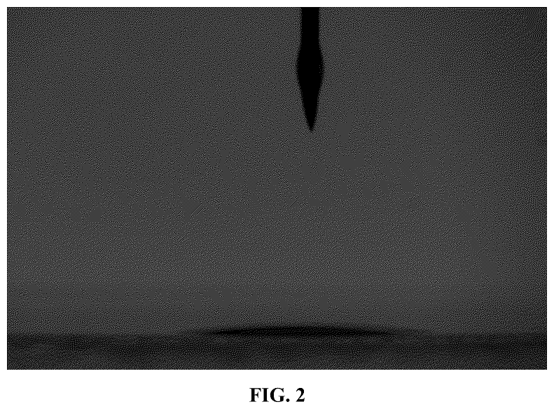

FIG. 3 is a schematic diagram of the PVK+TM3 film-water contact angle of 91.56° provided by the embodiment of the present disclosure;

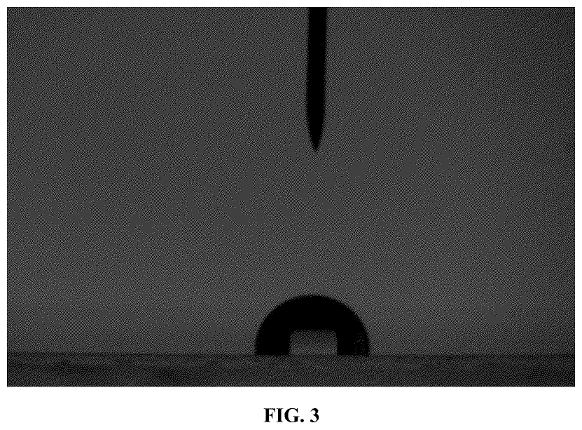

FIG. 4 is a schematic diagram of the PVK+TM3 film-n-octane contact angle of 8.43° provided by the embodiment of the present disclosure;

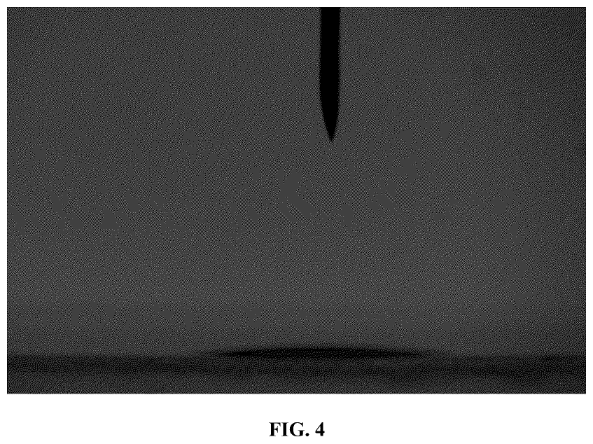

FIG. 5 is a J-V-L diagram of the TM3 molecule provided by the embodiment of the present disclosure.

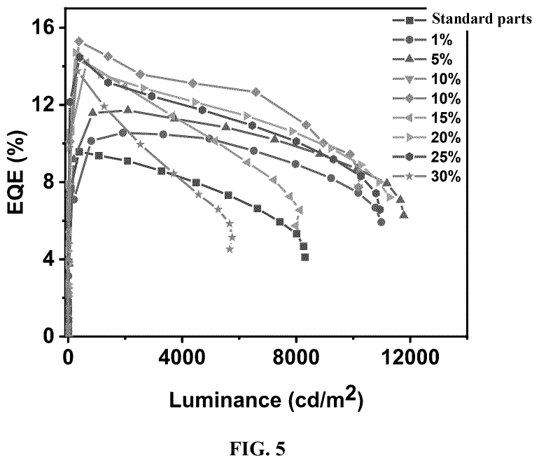

FIG. 6 is an EQE-L diagram of the TM3 molecule provided by the embodiment of the present disclosure.

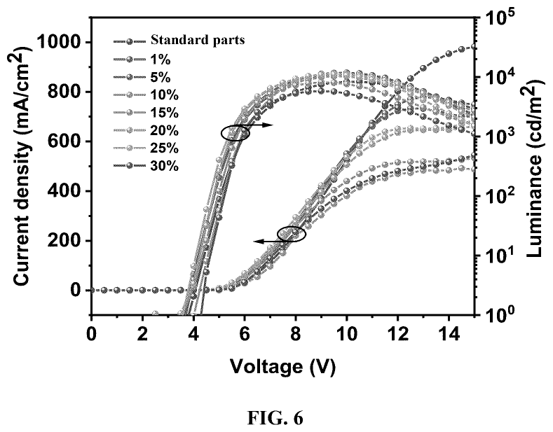

FIG. 7 is an electroluminescent spectrum diagram of the TM3 molecule provided by the embodiment of the present disclosure.

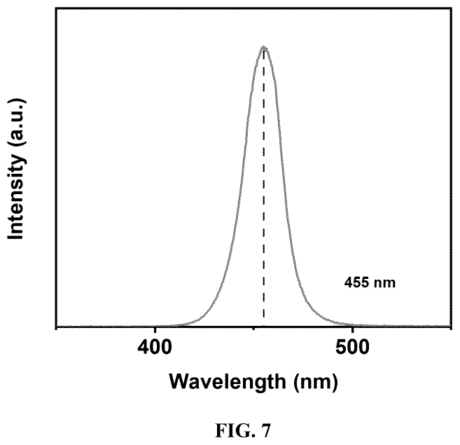

FIG. 8 is an infrared absorption schematic diagram of TM3, TM9, and TM14 molecules provided by the embodiment of the present disclosure.

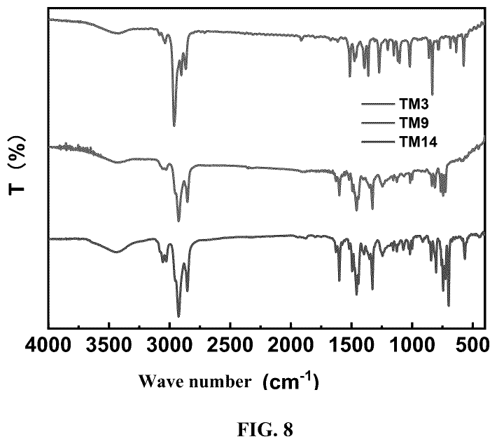

FIG. 9 is a fluorescence schematic diagram of TM3, TM9, and TM14 molecules provided by the embodiment of the present disclosure;

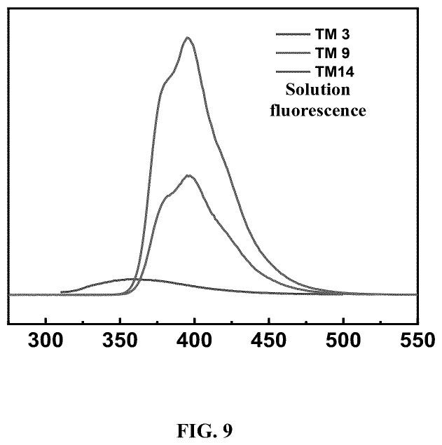

FIG. 10 is a UV absorption diagram of TM3, TM9, and TM14 molecules provided by the embodiment of the present disclosure;

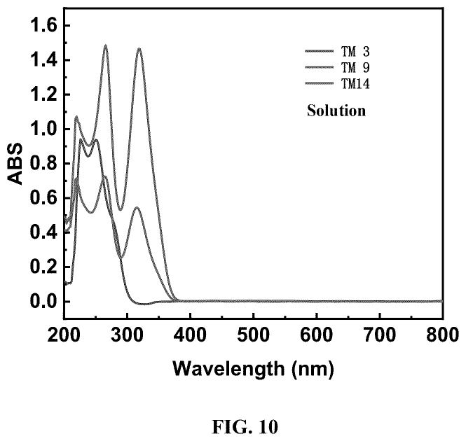

FIG. 11 shows a TM3-TGA schematic diagram provided by the embodiment of the present disclosure.

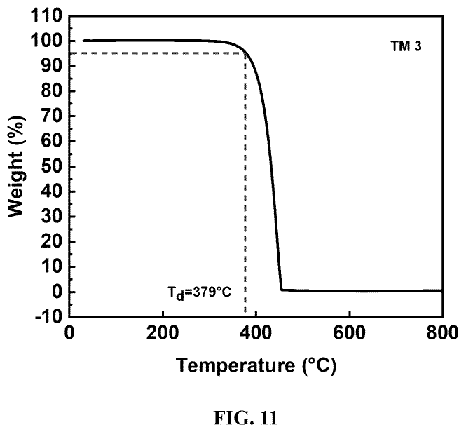

FIG. 12 shows a TM3-DSC schematic diagram provided by the embodiment of the present disclosure.

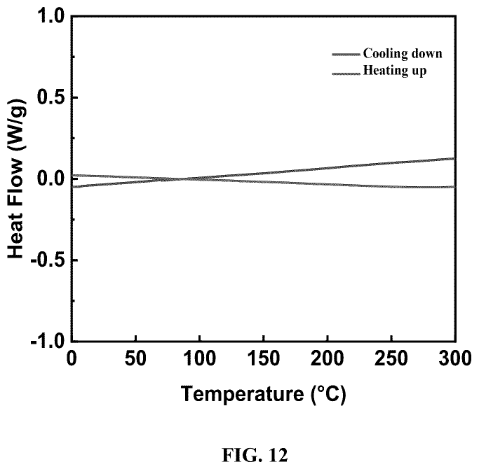

FIG. 13 shows a TM9-TGA schematic diagram provided by the embodiment of the present disclosure.

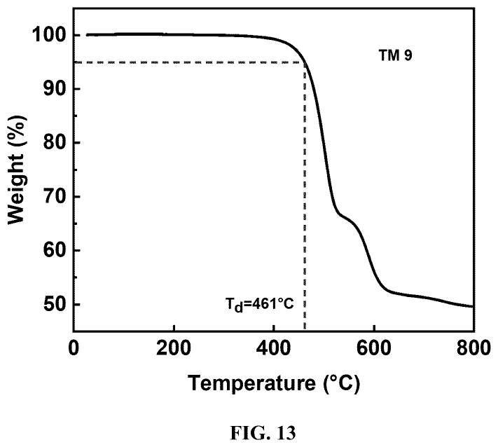

FIG. 14 shows a TM9-DSC schematic diagram provided by the embodiment of the present disclosure.

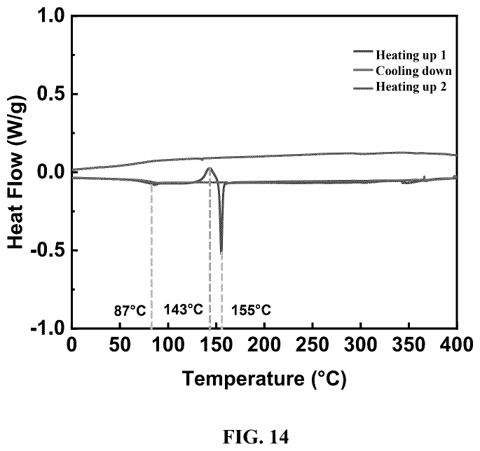

FIG. 15 shows a schematic diagram of TM14-TGA provided by the embodiment of the present disclosure.

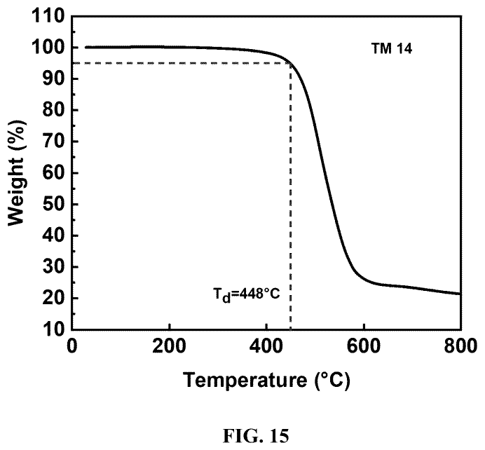

FIG. 16 shows a schematic diagram of TM14-DSC by the embodiment of the present disclosure.

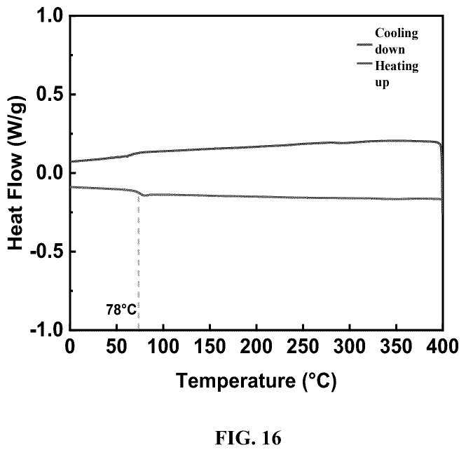

### DETAILED DESCRIPTION OF THE EMBODIMENTS

In the following, the specific implementation method of the present disclosure is further described in detail in combination with the drawings and implementation examples. The following embodiments are used to illustrate the present disclosure, but are not used to limit the scope of the present disclosure.

In order to better understand the purpose, structure, and function of the present disclosure, the following is a further detailed description of the present disclosure in combination with the attached figures.

According to some embodiments of this application, a synthetic method for hexaphenylbenzene-based organic small molecules is provided, the hexaphenylbenzene-based organic small molecules have one or more of the chemical structures shown in Formula I or Formula II:

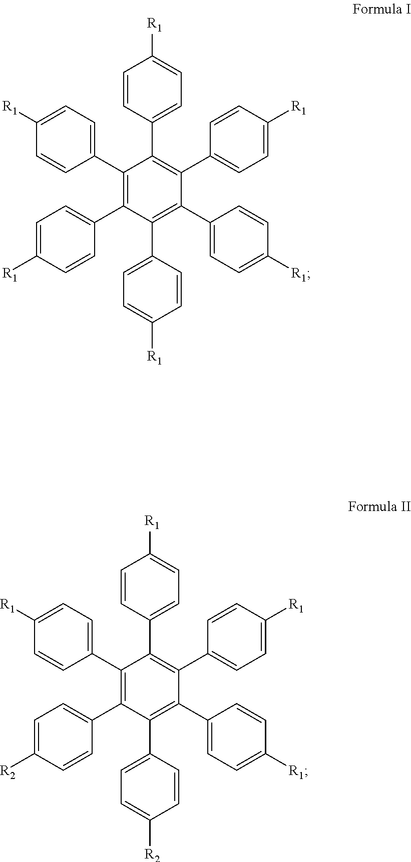

where R₁ and R₂ in Formula I or Formula II include:

One or several combinations of

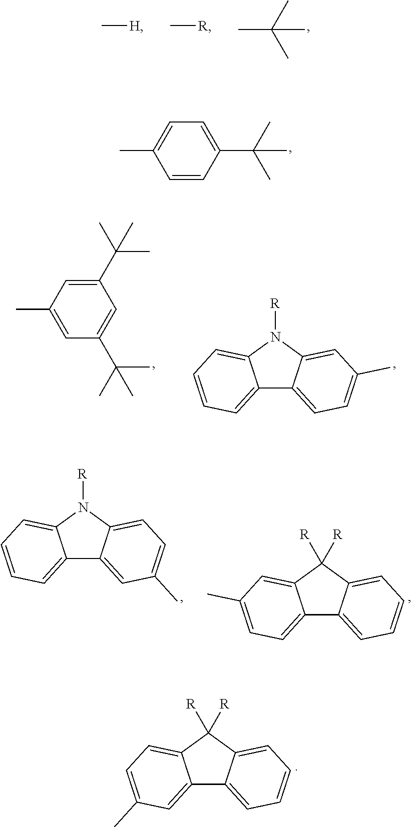

In some embodiments of this application, —R is a long-chain alkyl or long-chain alkoxy group and consists of the following 24 molecules:

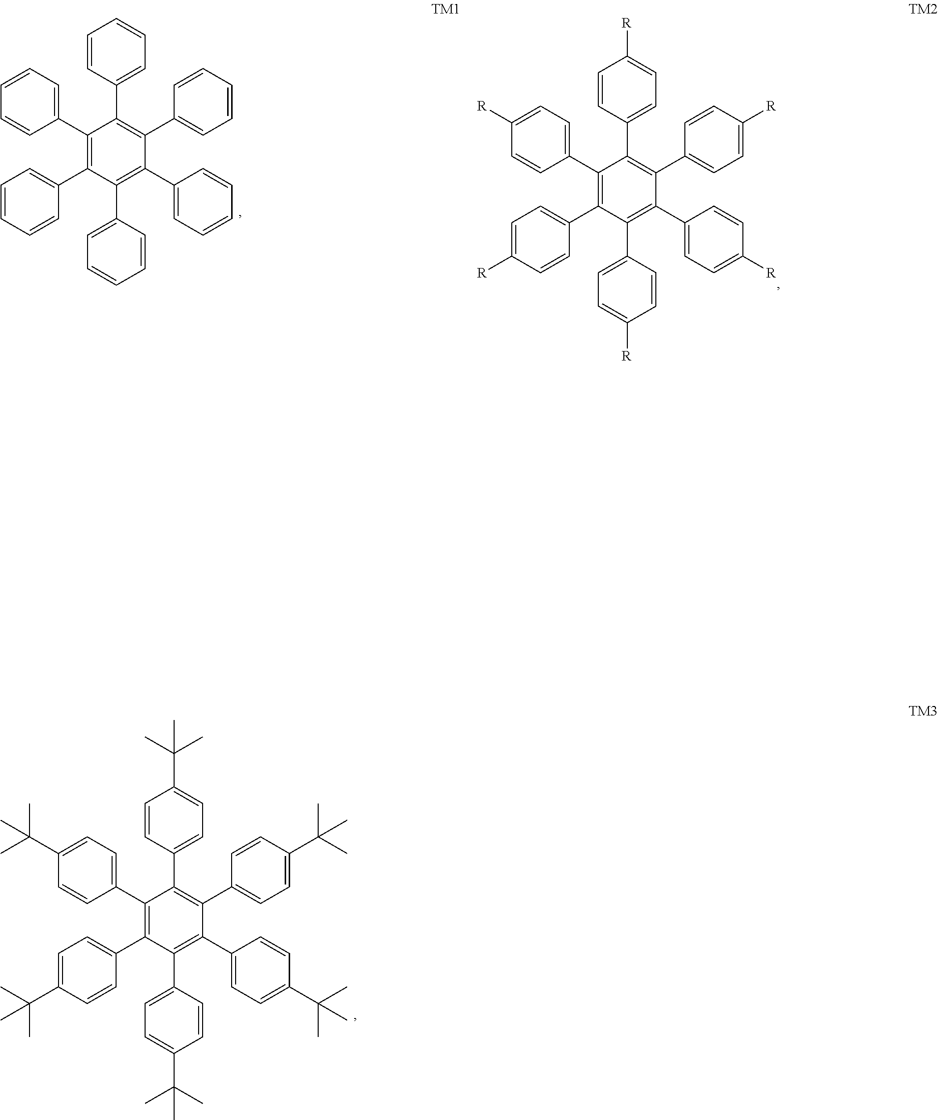

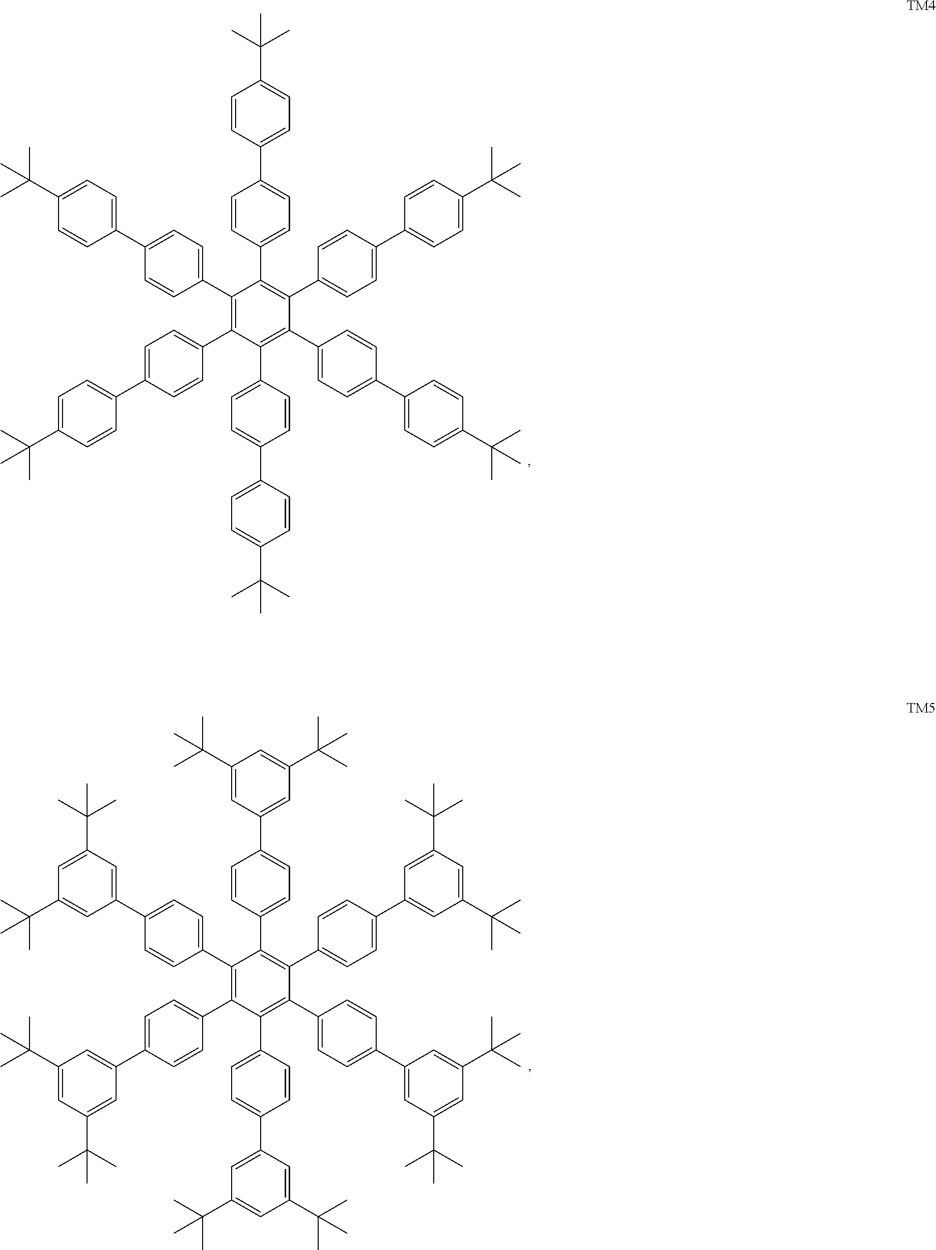

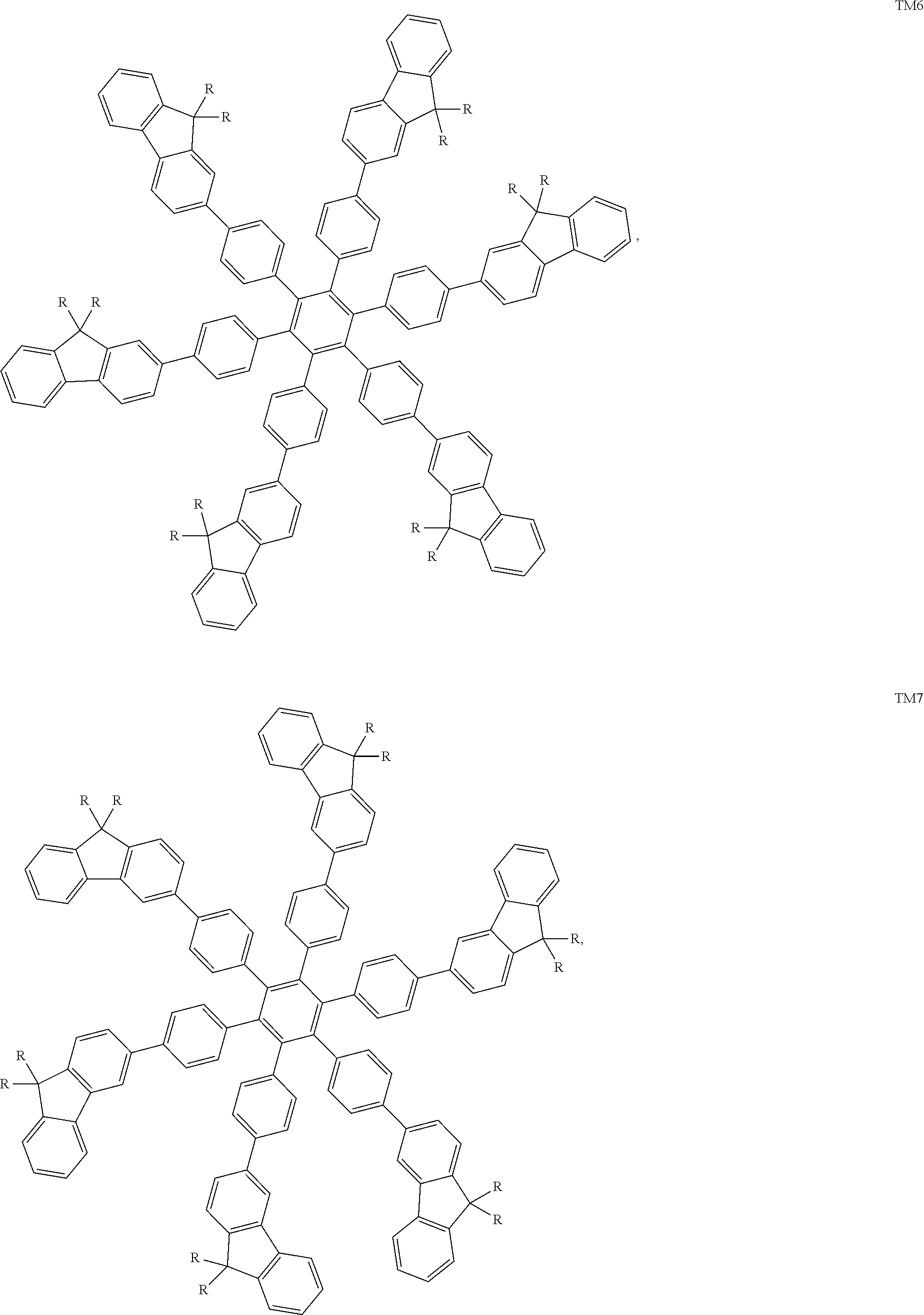

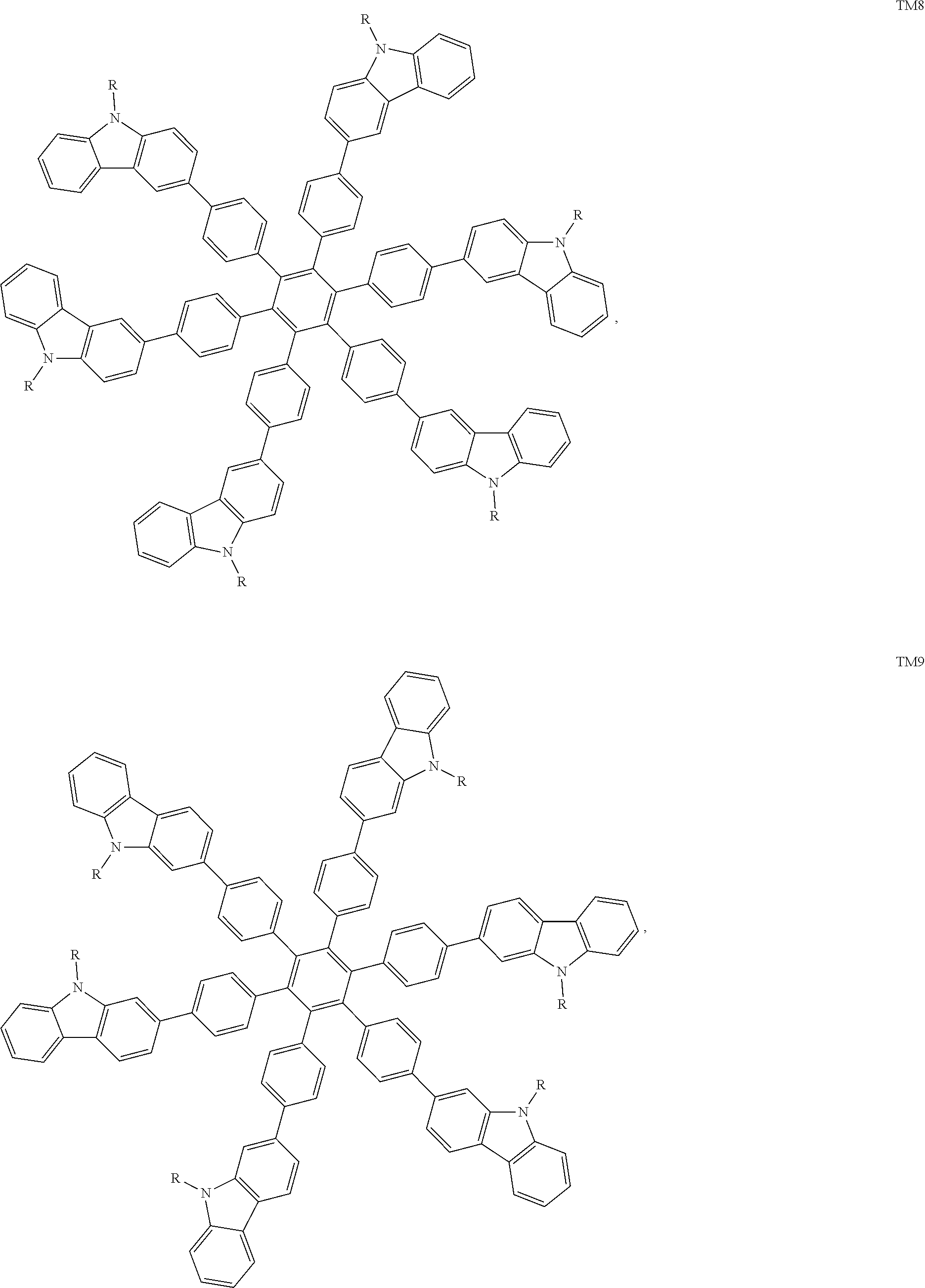

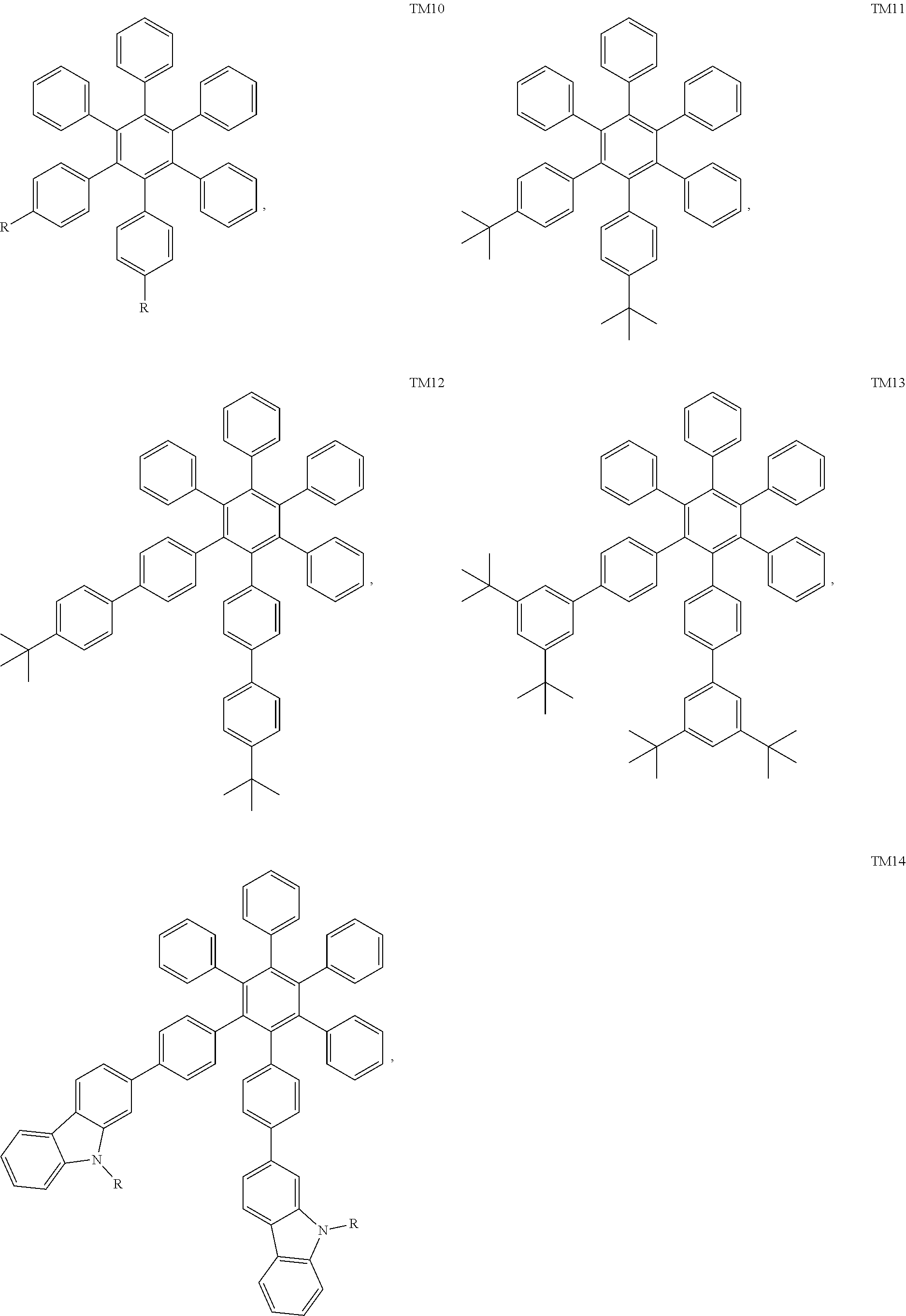

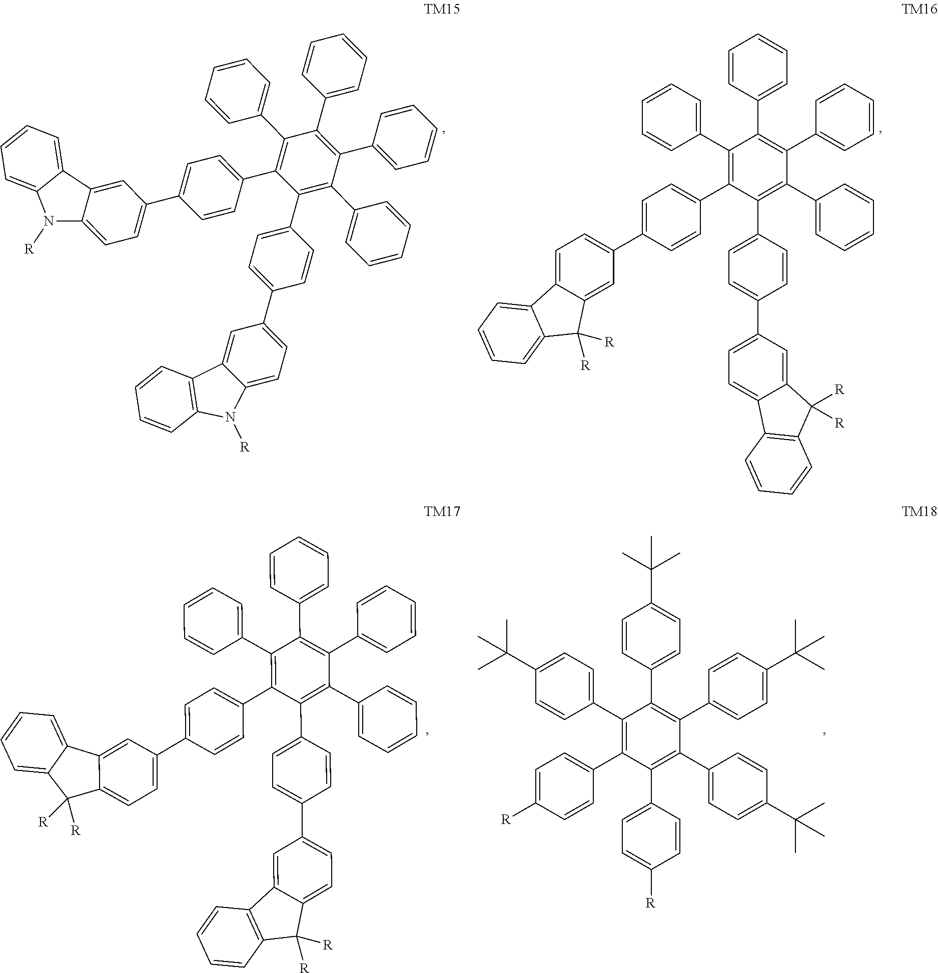

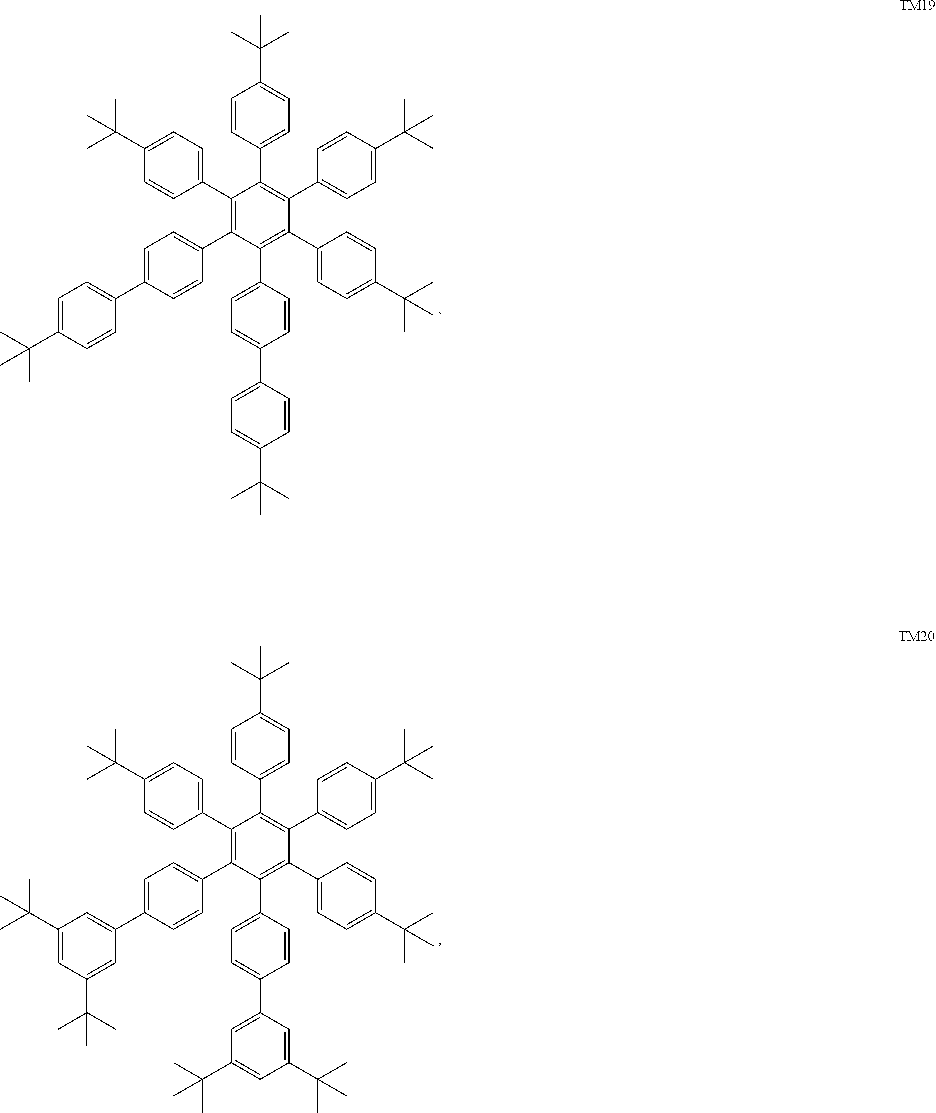

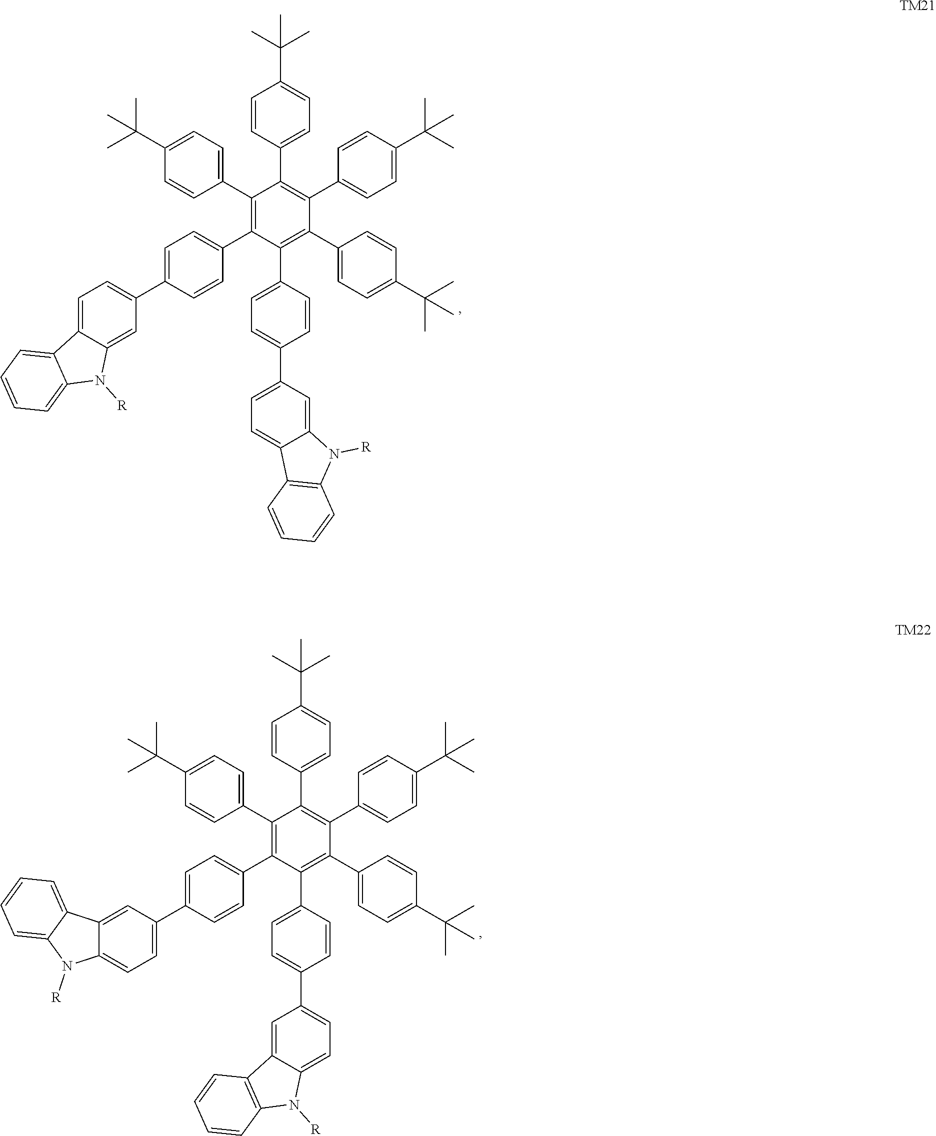

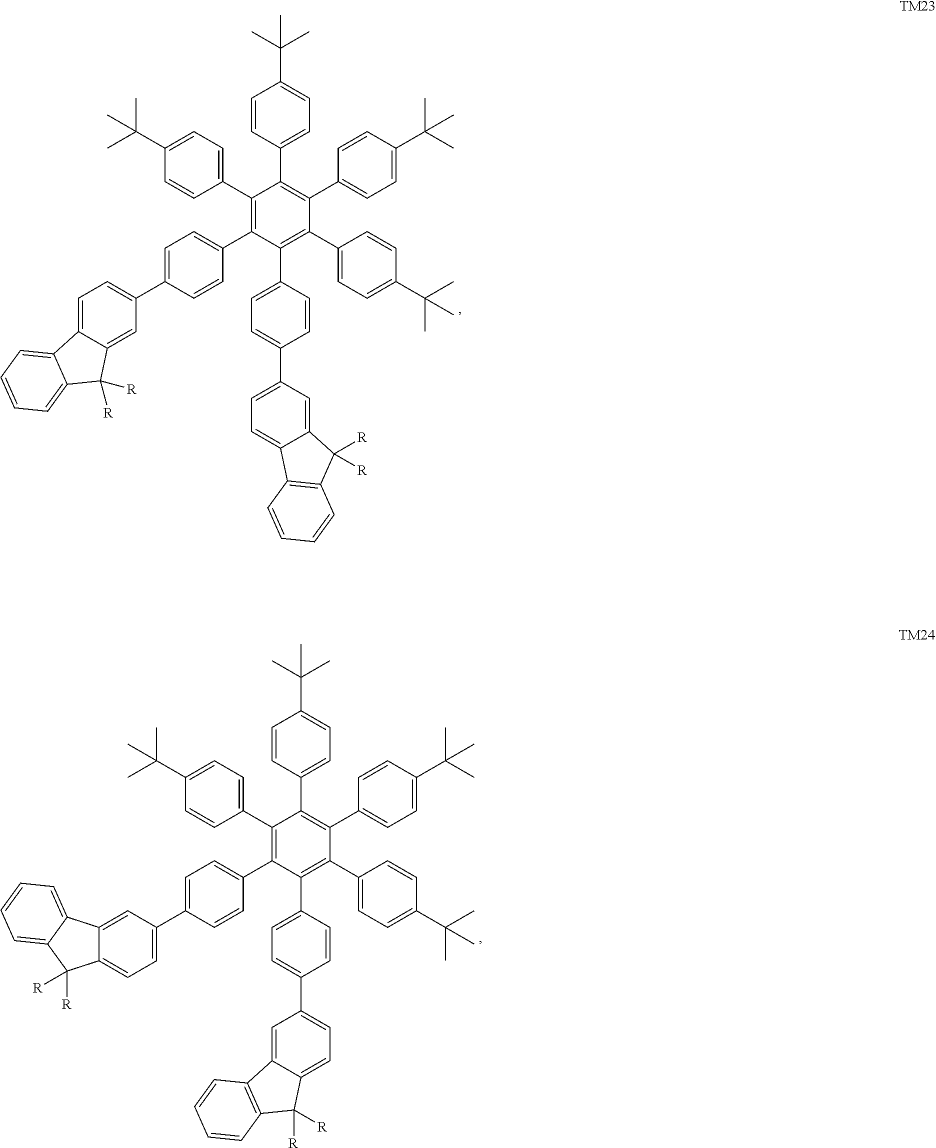

The synthesis method for the hexaphenylbenzene-based organic small molecules in Formula I includes the following steps:
Step 1) Under a protection of inert gas, the first intermediate is obtained by the reaction of iodobenzene derivatives and phenylacetylene derivatives with a molar ratio of 1:(1-1.5) as raw materials, triethylamine as a solvent, cuprous iodide, and bis(triphenylphosphine) palladium chloride as catalysts at room temperature for 10-15 h.
Step 2) Under the protection of inert gas, the first intermediate is used as the raw material, 1,4-dioxane as a solvent, and dicobalt octacarbonyl as a catalyst; the reaction is performed at 100-130° C. for 8-16 h to obtain the second intermediate, namely the first kind of compounds.
Step 3) Under the protection of inert gas, p-bis(4-bromophenyl)alkyne is used as a raw material, 1,4-dioxane as solvent, dicobalt octacarbonyl as catalyst, and the reaction is performed at 100-130° C. for 8-16 h to obtain the third intermediate.
Step 4) Under the protection of inert gas, the third intermediate with a molar ratio of 1:(6-12) and the boric acid or boron ester of the required side chain are used as raw materials, toluene/tetrahydrofuran as solvent, tetratriphenylphosphine palladium as catalyst, and tetraethylammonium hydroxide as base. The reaction is performed at 70-120° C. for 12-36 h to obtain the fourth intermediate, namely the hexaphenylbenzene-based organic small molecules in Formula I. The amount of boric acid or boron ester connected to the side chain should be as much as possible. Excess, as far as possible to reduce the formation of by-products, such molecules with shorter side chains have poor solubility, and can be dissolved by heating.

In some embodiments of this application, for a complex side chain of more than five carbons, the synthesis method for hexaphenylbenzene-based organic small molecules in Formula II includes the following steps:
Step 1) Under the protection of inert gas, using p-bis(4-bromophenyl)alkyne as a raw material, 1,4-dioxane as a solvent, and dicobalt octacarbonyl as a catalyst, performing a reaction at 100-130° C. for 8-16 h to obtain a third intermediate;
Step 2) Under the protection of inert gas, using the third intermediate with a molar ratio of 1:(6-12) and boric acid or boron ester of a required side chain as raw materials, toluene/tetrahydrofuran as a solvent, tetratriphenylphosphine palladium as a catalyst, tetraethylammonium hydroxide as a base, and reacting at 70-120° C. for 12-36 h to obtain a fourth intermediate, namely hexaphenylbenzene-based organic small molecules in Formula I.

In some embodiments of this application, the synthesis method of hexaphenylbenzene-based organic small molecules in Formula II includes the following steps:
Step 1) Under the protection of inert gas, diphenylethanedione and 1,3-diphenylacetone or 1,2-bis(4-(tert-butyl)phenyl) ethane-1,2-dione and 1,3-bis(4-(tert-butyl)phenyl) propan-2-one with a molar ratio of 1:1 is used as raw materials, tert-butanol as a solvent, potassium tert-butanol as a base, and reacted at 90-110° C. for 0.5-1 h to obtain the fifth intermediate.
Step 2) Under the protection of inert gas, p-bis(4-bromophenyl)alkyne with a molar ratio of 1:2-2.5 and the boric acid or boron ester of the required side chain are used as raw materials, toluene as a solvent, tetratriphenylphosphine palladium as a catalyst, tetraethylammonium hydroxide as a base, and reacted at 90-110° C. for 10-16 h to obtain the sixth intermediate.
Step 3) Under the protection of inert gas, the fifth and sixth intermediates with a molar ratio of 1:1 are used as raw materials, diphenyl ether as a solvent, and a reaction is performed at 200-260° C. for 20-24 h to obtain the seventh intermediate, namely the hexaphenylbenzene-based organic small molecules in Formula II.

In some embodiments of this application, the application of hexaphenylbenzene organic molecules in electroluminescent devices includes doping in a functional layer or directly as a functional layer modification interface.

The specific experimental steps of preparing QLED devices by doping hexaphenylbenzene-based organic small molecules in hole transport materials are as follows:

Common QLED device structures include ITO/HIL/HTL/EML/ETL/AL.

Firstly, the ITO substrate is pretreated, including solvent cleaning and oxygen plasma cleaning. Solvent cleaning is to ultrasonically clean the etched ITO substrate with cleaning agent, deionized water, deionized water, recycled ethanol, and anhydrous ethanol for 20-30 min, respectively; the beaker containing the ITO substrate and anhydrous ethanol solution is placed on a heating stage and the temperature is set to 120-150° C., when the anhydrous ethanol is slightly boiled, the surface solvent is blown off with a nitrogen gas flow. The oxygen plasma cleaning instrument is used for cleaning for 10 min.
(1) The PEDOT:PSS solution is spin-coated on the surface of the pretreated ITO substrate at a speed of 2000-4000 rpm for 30 s, and heated in air at 100-150° C. for 15-30 min to form a hole injection layer (HIL) on the surface of the ITO substrate.
(2) 8-14 mg/ml of PVK solution and 5-10 mg/ml of the above-mentioned hexaphenylbenzene organic molecular solution are configured, the solvent can be chlorobenzene or toluene, and other good solvents. The hexaphenylbenzene organic molecular solution is doped into the PVK solution with 1-30% VOL, and fully shaken and mixed evenly. The hole transport layer (HTL) solution is spin-coated on the HIL film at a speed of 2000-4000 rpm for 30 s, and heated at 100-150° C. for 15-30 min in air. After recovering to room temperature, the film at the electrode required for the test is erased, and a hole transport layer (HTL) is formed on the surface of the hole injection layer.
(3) The film obtained in (2) is transferred to a glove box of inert gas, and the emitting layer quantum dots (QD) n-octane/toluene solution is spin-coated at a speed of 2000-4000 rpm for 30 s. The solution is heated at 80-100° C. for 5-10 min in a nitrogen atmosphere to form an emitting layer (EML) on the surface of the hole transport layer.
(4) The film obtained in (3) is spin-coated with an electron transport layer (ETL) of 15-25 mg/ml ZnO or ZnMgO ethanol solution for 30 s at a rotation speed of 2000-4000 rpm, and heated at 80-100° C. in a nitrogen atmosphere for 15-30 min. After recovering to room temperature, the film at the electrode required for the test is erased, and an electron transport layer (ETL) is formed on the surface of the emitting layer.
(5) The spin-coated ITO substrate obtained by (4) is placed on the mask and placed in the vacuum evaporation chamber. The metal cathode is deposited at a rate of 8-10 Å/s at a vacuum of less than 6×10⁻⁴ Pa to obtain a QLED device.

### Example 1

In this embodiment, some of the technical features of the above embodiment are adopted. The synthesis steps of TM3 include:

### Step 1:

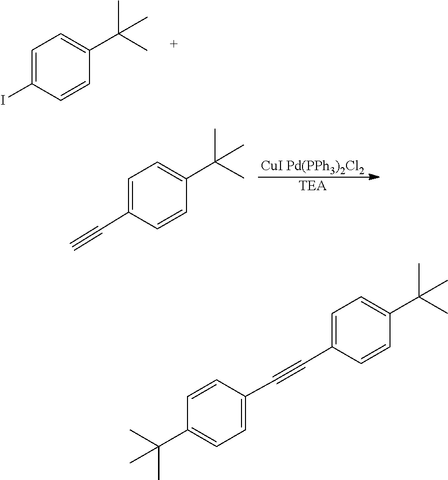

1-tert-butyl-4-iodobenzene (1.00 g, 3.84 mmol), cuprous iodide (17.50 mg, 91.89 umol), bis-triphenylphosphine palladium chloride (18.10 mg, 25.79 umol) and 50 ml triethylamine are added to a 100 ml double-necked flask. The reaction system is deoxygenated, and 4-tert-butylphenylacetylene (608.35 mg, 3.84 mmol) is added drop by drop under argon protection, and the reaction is completed at room temperature for 10 h. The reaction is monitored by thin-layer chromatography (developer:petroleum ether). After the reaction is completed, it is washed with saturated salt water, extracted with dichloromethane, and the solvent is removed by vacuum evaporation. The crude product is separated and purified by silica gel column chromatography (eluent:petroleum ether). Atotal of 0.9563 g of white solid compound 1-1 is obtained with a yield of 85.74%.

1H NMR (400 MHz, Chloroform-d) δ 7.38 (d, J=8.3 Hz, 4H), 7.27 (d, J=8.3 Hz, 4H), 1.24 (s, 18H).

13C NMR (101 MHz, CDCl3) δ 151.32,131.30,125.32,120.48,88.87,77.35,77.03,76.72,34.79,31.21.

### Step 3:

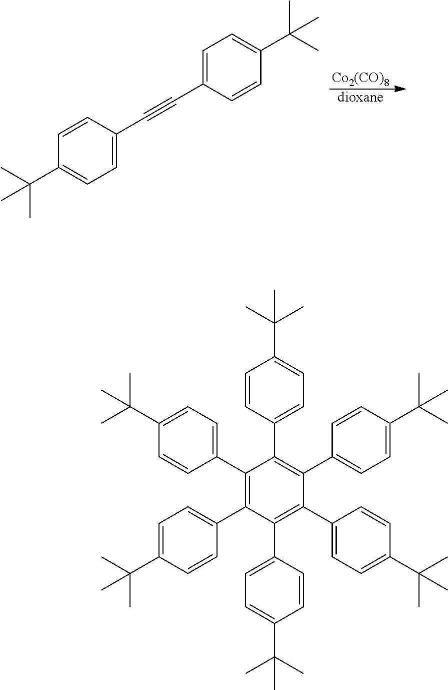

Compounds 1-1 (0.87 g, 3.00 mmol), dicobalt octacarbonyl (153.88 mg, 0.45 mmol), and 1,4-dioxane (30 ml) are added to a 50 ml double-necked flask. The reaction is carried out at 115° C. for 10 h under argon protection. The reaction is monitored by thin-layer chromatography (developer:petroleum ether:dichloromethane=5:1, V/V). After the reaction is completed, the solvent is removed by vacuum evaporation, and the crude product is separated and purified by silica gel column chromatography (eluent:petroleum ether:dichloromethane=8:1, V/V). The white solid 1-2, namely TM3, is 0.6645 g, with a yield of 76.38%.

1H NMR (400 MHz, Chloroform-d) δ 6.81 (d, J=8.3 Hz, 2H), 6.68 (d, J=8.3 Hz, 2H), 1.10 (s, 9H).

13C NMR (101 MHz, CDCl3) δ 147.32, 140.27, 137.97, 131.09, 123.01, 77.34, 77.02, 76.70, 34.05, 31.20.

### Example 2

In this example, some of the technical features of the above example are adopted, in which the synthesis step of TM9 is

### Step 1:

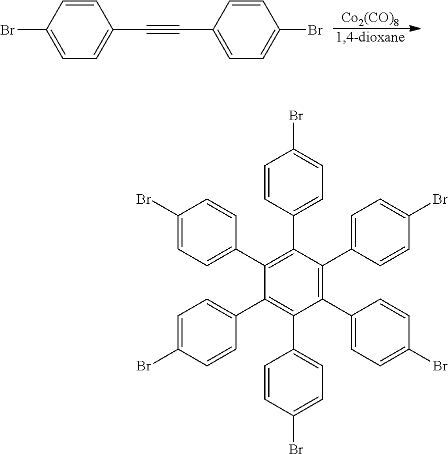 [SMILES: Brc1ccc(C#Cc2ccc(Br)cc2)cc1 ; Brc1ccc(-c2c(-c3ccc(Br)cc3)c(-c3ccc(Br)cc3)c(-c3ccc(Br)cc3)c(-c3ccc(Br)cc3)c2-c2ccc(Br)cc2)cc1]

Bis(4-bromophenyl)alkyne (1.008 g, 3.00 mmol), dicobalt octacarbonyl (0.1539 g, 0.45 mmol), and 15 ml 1,4-dioxane are added to a 50 ml double-necked flask. The reaction is carried out at 120° C. for 8 h under argon protection. The reaction is monitored by thin-layer chromatography (developing agent:petroleum ether:dichloromethane=5:1, V/V). After the reaction is completed, the solvent is removed by vacuum evaporation, dichloromethane is dissolved, and methanol is recrystallized to obtain a white solid compound 2-1 with a total of 0.5040 g and a yield of 50.00%.

1H NMR (800 MHz, Chloroform-d) δ 7.05 (d, J=8.4 Hz, 1H), 6.61 (d, J=8.4 Hz, 1H).

13C NMR (201 MHz, CDCl3) δ 138.50,137.36,131.51,129.41,119.28,76.15,75.99,75.83.

### Step 2:

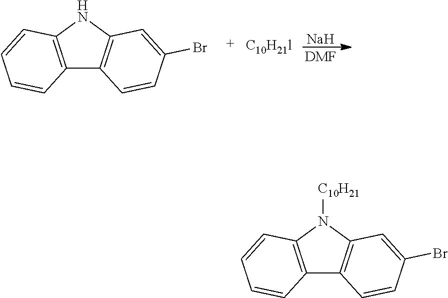

2-Bromocarbazole (1.9689 g, 8.00 mmol), sodium hydride (0.6400 g, 16.00 mmol) (60% dispersed in mineral oil), and DMF (28 ml) are added into a 100 ml three-necked flask. The reaction is performed at room temperature for 40 min, and 1-iododecane (2.5745 g, 9.60 mmol) is slowly added and reacted at room temperature for 1 hour. The reaction is monitored by thin-layer chromatography (developing agent:petroleum ether). After the reaction is completed, it is quenched with deionized water, washed with a large amount of saturated salt water, extracted with dichloromethane, collected the organic phase, and evaporated under reduced pressure to remove the solvent. The crude product is separated and purified by silica gel column chromatography (eluent:petroleum ether), and a total of 2.8592 g of transparent oil 2-2 is obtained, with a yield of 92.50%.

1H NMR (800 MHz, Chloroform-d) δ 7.98 (d, J=7.7 Hz, 1H), 7.85 (d, J=8.2 Hz, 1H), 7.46 (s, 1H), 7.40 (t, J=7.6 Hz, 1H), 7.31 (d, J=8.1 Hz, 1H), 7.24 (d, J=8.2 Hz, 1H), 7.16 (t, J=7.4 Hz, 1H), 4.16 (t, J=7.4 Hz, 2H), 1.77 (p, J=7.4 Hz, 2H), 1.17 (s, 14H), 0.80 (t, J=7.1 Hz, 3H).

13C NMR (201 MHz, CDCl3) δ 141.37, 140.69, 126.16, 122.43, 122.00, 121.90, 121.60, 120.47, 119.41, 119.34, 111.88, 109.03, 77.32, 77.16, 77.00, 43.36, 31.99, 29.67, 29.64, 29.51, 29.41, 29.00, 27.39, 22.81, 14.26.

### Step 3:

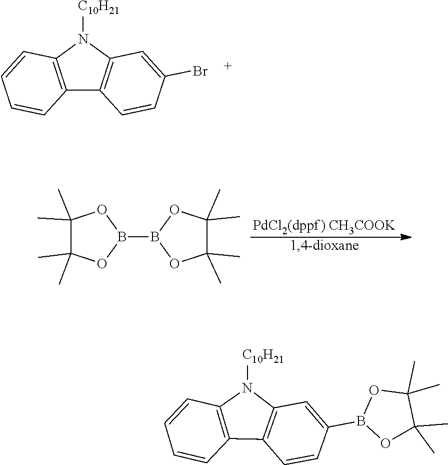

Compound 2-2 (3.0910 g, 8 mmol), bifenoxol borate (2.4378 g, 9.6 mmol), potassium acetate (6.2720 g, 64 mmol), [1,1′-bis(diphenylphosphino) ferrocene]palladium chloride (0.4683 g, 0.64 mmol), and 150 ml 1,4-dioxane are added to a 250 ml three-necked flask. The reaction is performed at room temperature for 30 min under argon protection and then heated to 80° C. for 16 h. The reaction is monitored by thin-layer chromatography (developing agent:petroleum ether:dichloromethane=5:1, V/V). After the reaction is completed, the filtrate is filtered and evaporated under reduced pressure to remove the solvent to obtain the crude product. The product is separated and purified by silica gel column chromatography (eluent:petroleum ether:dichloromethane=8:1, V/V) to obtain a total of 2.9370 g of transparent oil 2-3, with a yield of 84.70%.

1H NMR (800 MHz, Chloroform-d) δ 8.03 (t, J=8.1 Hz, 2H), 7.80 (s, 1H), 7.61 (d, J=7.7 Hz, 1H), 7.40 (t, J=7.6 Hz, 1H), 7.33 (d, J=8.2 Hz, 1H), 7.14 (t, J=7.4 Hz, 1H). 4.26 (t, J=7.4 Hz, 2H), 1.80 (p, J=7.6 Hz, 2H), 1.33 (s, 14H), 1.16 (s, 12H), 0.80 (t, J=7.2 Hz, 3H).

13C NMR (201 MHz, CDCl3) δ 139.90,138.88,125.10,124.29,123.89,121.53,119.73,118.56,117.60,113.99,107.80,82.72, 76.15,75.99,75.83,41.96,30.84,28.52,28.50,28.40,28.25,28.05,26.21. 23.91, 21.64, 13.09.

### Step 4:

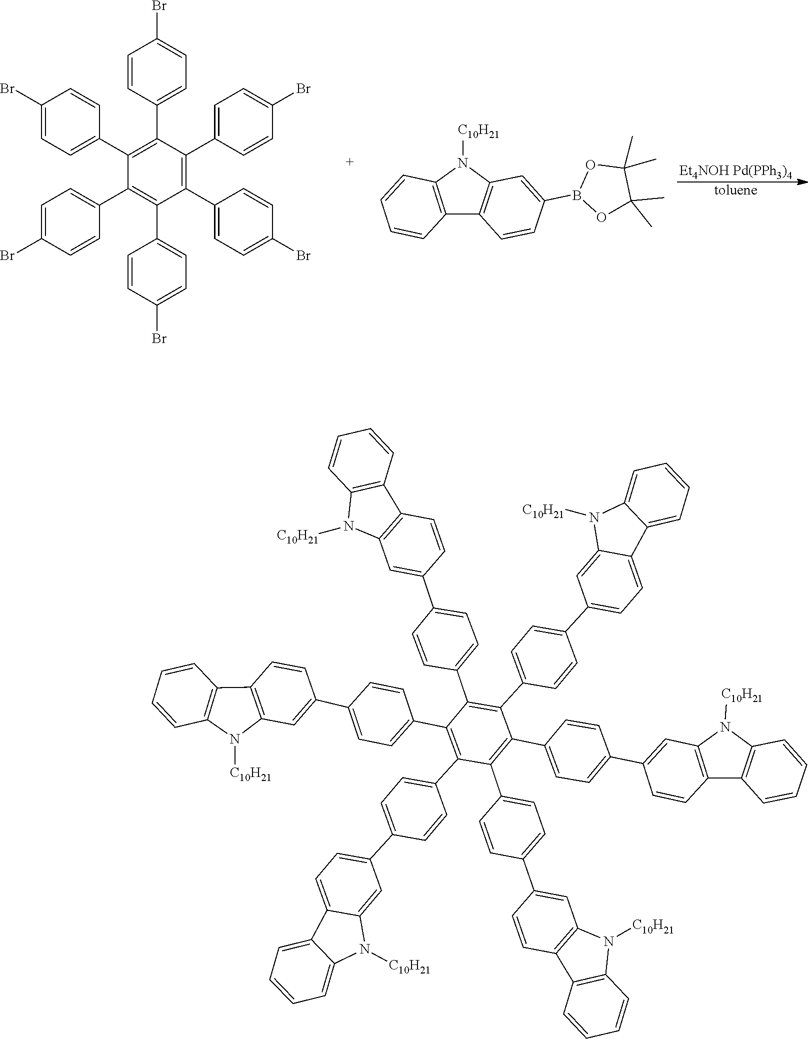

Compound 2-1 (1.00 g, 0.9920 mmol), compound 2-3 (3.8328 g, 9.9198 mmol), tetratriphenylphosphine palladium (0.1146 g, 0.0992 mmol), and 40 ml toluene are added to a 100 ml three-necked flask. Under the protection of argon, 20 ml 20% tetraethylammonium hydroxide is added and heated to 100° C. for 48 h. The reaction is monitored by thin-layer chromatography (developer:petroleum ether:dichloromethane=2:1, V/V). After the reaction is completed, the saturated salt water is washed, the dichloromethane is extracted, the organic phase is collected, the solvent is removed by vacuum evaporation, and the separation and purification are performed by silica gel column chromatography (eluent:petroleum ether: dichloromethane=5:1, V/V). The white solid compounds 2-4 are obtained with a total of 1.9265 g and a yield of 82.03%.

1H NMR (400 MHz, Chloroform-d) δ 8.04 (t, J=8.4 Hz, 2H), 7.48 (s, 1H), 7.43 (d, J=8.2 Hz, 3H), 7.37 (dd, J=12.3, 8.7 Hz, 2H), 7.21 (t, J=7.5 Hz, 1H), 7.16 (d, J=8.2 Hz, 2H). 4.20 (t, J=7.0 Hz, 2H), 1.79 (p, J=7.2 Hz, 2H), 1.33-1.10 (m, 14H), 0.88 (t, J=7.0 Hz, 3H).

13C NMR (101 MHz, CDCl3) δ 140.94, 140.91, 140.52, 139.70, 138.68, 138.47, 132.14, 125.85, 125.45, 122.61, 121.91, 120.41, 120.27, 118.74, 118.17, 108.65, 106.62, 77.36, 77.04, 76.73, 42.89, 31.87. 29.53, 29.49, 29.38, 29.28, 28.94, 27.22, 22.69, 14.16.

### Example 3

In this embodiment, some of the technical features of the above example are adopted, in which the synthesis step of TM14 is:

### Step 1:

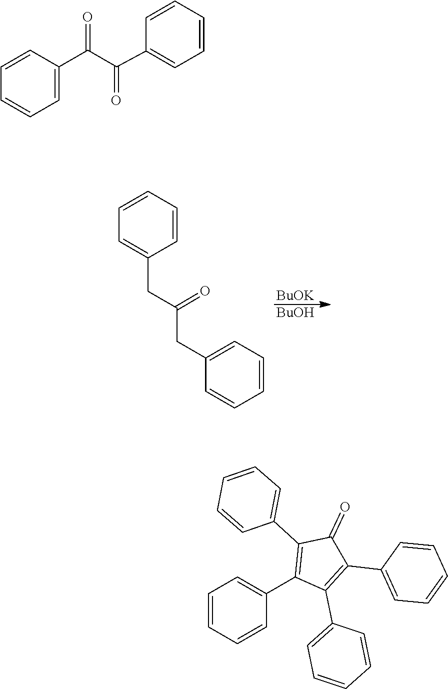 [SMILES: O=C(C(=O)c1ccccc1)c1ccccc1 ; O=C(Cc1ccccc1)Cc1ccccc1 ; O=C1C(c2ccccc2)=C(c2ccccc2)C(c2ccccc2)=C1c1ccccc1]

Diphenylethanone (3.15 g, 15 mmol), 1,3-diphenylacetone (3.15 g, 15 mmol), and tert-butyl alcohol (60 mL) are added to 100 ml three-mouth flask. The temperature is raised to 100° C. under argon protection, and potassium tert-butyl alcohol (0.84 g, 7.5 mmol) is added to react for 30 min. The reaction is monitored by thin-layer chromatography (developing agent:petroleum ether:dichloromethane=1:1, V/V). After the reaction is completed, it is cooled to room temperature, recrystallized in methanol, and filtered to obtain a total of 4.1639 g of black purple solid compound 3-1, with a yield of 72.20%.

1H NMR (400 MHz, DMSO-d6) δ 7.32-7.14 (m, 16H), 6.98 (d, J=6.8 Hz, 4H).

13C NMR (201 MHz, CDCl3) δ 200.35, 154.49, 133.07, 130.75, 130.15, 129.34, 128.51, 128.04, 127.99, 127.47, 125.32, 77.20, 77.04, 76.88.

### Step 2:

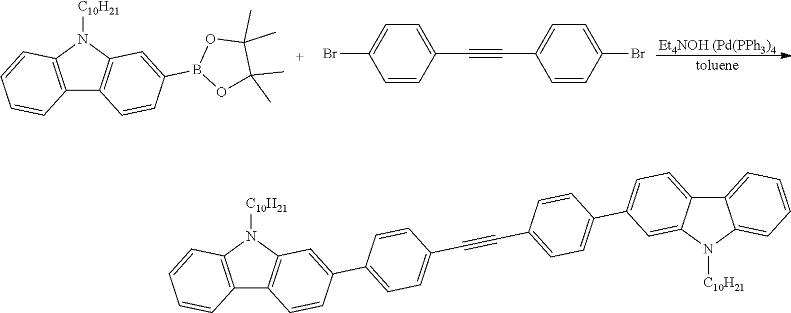

Bis(4-bromophenyl)alkyne (1.008 g, 3.00 mmol), compound 2-3 (2.8607 g, 6.60 mmol), tetratriphenylphosphine palladium (0.0693 g, 0.06 mmol), and 15 ml toluene were added to a 50 ml three-necked flask. 5 ml 20% tetraethylammonium hydroxide was added under argon protection and heated to 100° C. for 14 h. The reaction was monitored by thin-layer chromatography (developing agent:petroleum ether:dichloromethane=4:1, V/V). After the reaction is completed, the saturated salt water is washed, dichloromethane is extracted, and the solvent is removed by vacuum evaporation. Silica gel column chromatography is used for separation and purification (eluent:petroleum ether:dichloromethane=6:1, V/V), and a total of 1.6478 g of white solid compound 3-2 was obtained, with a yield of 69.60%.

1H NMR (800 MHz, Chloroform-d) δ 8.09 (d, J=7.9 Hz, 1H), 8.05 (d, J=7.6 Hz, 1H), 7.68 (d, J=7.7 Hz, 2H), 7.61 (d, J=7.8 Hz, 2H), 7.54 (s, 1H), 7.42 (dd, J=17.5, 7.9 Hz, 2H), 7.36 (d, J=8.1 Hz, 1H), 7.18 (d, J=7.4 Hz, 1H), 4.29 (t, J=7.1 Hz, 2H), 1.85 (p, J=7.2 Hz, 2H), 1.35 (dd, J=15.7, 8.0 Hz, 2H), 1.28 (p, J=7.2 Hz, 2H), 1.18 (dd, J=16.4, 10.0 Hz, 12H), 0.80 (t, J=7.3 Hz, 3H).

13C NMR (201 MHz, CDCl3) δ 142.07, 141.06, 140.96, 138.15, 132.06, 131.58, 127.49, 125.79, 122.55, 122.43, 121.96, 120.69, 120.46, 118.98, 118.33, 108.77, 107.07, 90.17, 77.18, 77.02, 76.86, 43.12, 31.87, 29.72, 29.57, 29.54, 29.44, 29.30, 29.02, 27.35, 22.68, 14.13.

### Step 3:

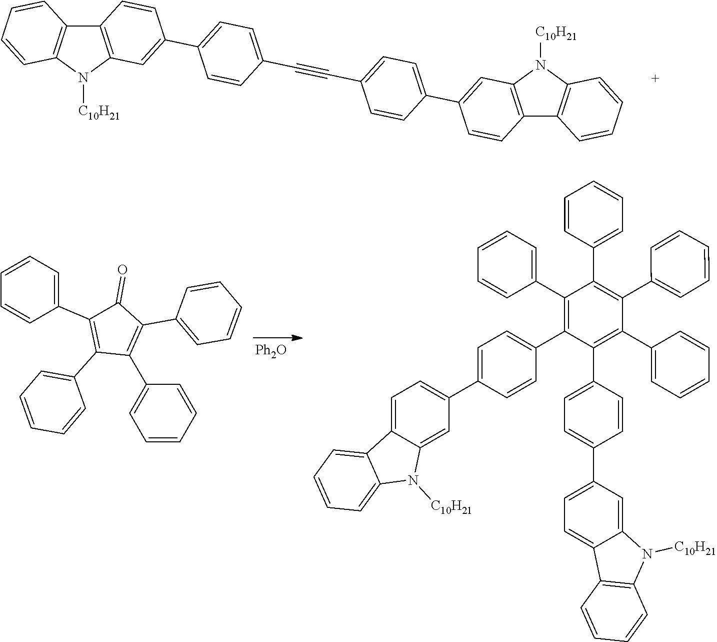

Compounds 3-2 (1.5783 g, 2.00 mmol), 3-1 (0.9228 g, 2.40 mmol), and 15 ml diphenyl ether are added to a 50 ml double-necked flask. The reaction is heated to 200° C. for 20 h under argon protection, and the reaction is monitored by thin-layer chromatography (developer:petroleum ether:dichloromethane=1:1, V/V). After the reaction is completely cooled to room temperature, silica gel column chromatography is used for separation and purification (eluent:petroleum ether:dichloromethane=6:1, V/V), and white solid compounds 3-3 are obtained. Atotal of 1.2739 g, with a yield of 55.60%.

1H NMR (400 MHz, Chloroform-d) δ 7.93 (dd, J=12.6, 7.9 Hz, 2H), 7.37-7.30 (m, 2H), 7.29-7.19 (m, 4H), 7.10 (t, J=7.4 Hz, 1H), 6.93 (d, J=8.1 Hz, 2H), 6.87-6.74 (m, 10H). 4.14 (t, J=7.1 Hz, 2H), 1.72 (p, J=7.1 Hz, 2H), 1.15 (d, J=25.0 Hz, 14H), 0.78 (t, J=6.9 Hz, 3H).

13C NMR (101 MHz, CDCl3) δ 140.92, 140.89, 140.68, 140.55, 140.53, 140.08, 139.59, 138.50, 138.50, 131.98, 131.53, 131.47, 126.75, 126.63, 125.66, 125.43, 125.28, 125.24, 122.61, 121.85, 120.35. 120.27, 118.73, 118.15, 108.64, 106.60, 77.36, 77.05, 76.73, 42.94, 31.86, 29.54, 29.50, 29.42, 29.27, 28.97, 27.27, 22.68, 14.16.

### Application Example 1 (Taking TM3 as an Example)

Pretreatment of the ITO substrate prior to use can enhance the work function of the conductive anode, reduce the hole injection barrier between the anode and the hole injection layer (HIL), and improve the wettability of the ITO surface. These improvements facilitate the formation of the HIL and contribute to the overall performance of the resulting QLED device.

Using a contact angle measuring instrument, the contact angles of the film to water and to the quantum dot solvent n-octane were measured before and after doping PVK with TM3. The contact angle of the film with n-octane decreased from 9.83° (before doping) to 8.43° (after doping), indicating enhanced wettability toward n-octane, which promotes uniform film formation of the quantum dot emission layer. Meanwhile, the contact angles with water are 90.63° (before doping) and 91.560 (after doping), confirming good hydrophobicity in both cases and the ability to mitigate detrimental environmental moisture effects on the device.

### Application Example 2 (Taking TM3 as an Example)

The procedure for fabricating a QLED device using TM3-doped PVK as the hole transport layer (HTL) is as follows:
(1) The ITO glass substrate is ultrasonically cleaned sequentially with detergent, deionized water (twice), recycled ethanol, and anhydrous ethanol, each for 30 minutes. The substrate in anhydrous ethanol is placed on a hotplate set at 140° C. Once the ethanol reaches a gentle boil, the surface is dried using a nitrogen stream. The dried ITO glass is then treated with an oxygen plasma cleaner for 10 minutes to obtain a pretreated ITO substrate. PEDOT:PSS 8000 solution is diluted with anhydrous ethanol in a 3:7 volume ratio and filtered through a disposable syringe filter. Then, 40 μL of the filtered solution is spin-coated onto the pretreated ITO substrate at 4000 rpm for 30 s. The film is annealed on a hotplate at 140° C. for 20 minutes to form the HIL.
(2) A 10 mg/mL PVK solution in chlorobenzene and a 5 mg/mL TM3 solution in chlorobenzene are prepared. The TM3 solution is doped into the PVK solution at 1-30% by volume and thoroughly mixed. The resulting HTL solution is spin-coated onto the HIL at 4000 rpm for 30 s, followed by annealing at 140° C. for 30 minutes in air. After cooling to room temperature, the film over the test electrode area is removed to define the HTL.
(3) The sample from (2) is transferred into an inert-atmosphere glovebox. A quantum dot (QD) emission layer is deposited by spin-coating a QD n-octane solution at 2000 rpm for 30 s, followed by thermal annealing at 100° C. for 5 minutes under nitrogen.
(4) An electron transport layer (ETL) of ZnMgO solution was spin-coated onto the emission layer at 2000 rpm for 30 s, annealed at 80° C. for 30 minutes under nitrogen, and cooled to room temperature. The film over the electrode area is again removed to define the ETL.
(5) The substrate from (4) is aligned under a shadow mask and loaded into a thermal evaporation chamber. A metal cathode is deposited at a rate of 8-10 Å/s under a vacuum better than 6×10⁻⁴ Pa to complete the QLED device.

### Device Characterization

The current density-voltage-luminance (J-V-L) characteristics and external quantum efficiency-luminance (EQE-L) curves are measured using a Keithley 2400 source meter and a calibrated silicon photodiode. The QLED device incorporating TM3 exhibited a maximum luminance of 10,221 cd/m², a maximum current efficiency (CEmax) of 5.29 cd/A, a maximum power efficiency of 3.02 lm/W, and an electroluminescence peak at 455 nm.

In the context of this application, it should be understood that the orientation or positional relationships indicated by terms such as “center”, “up”, “down”, “front”, “back”, “left”, “right”, “vertical”, “horizontal”, “top”, “bottom”, “inside”, and “outside” are based on the orientations or positional relationships shown in the accompanying drawings. These terms are used solely to facilitate the description of the application and to simplify the explanation, and are not to be construed as implying that the referred device or component must have a specific orientation or be constructed and operated in a specific orientation. Therefore, these terms should not be interpreted as limiting the scope of the application.

The terms “first” and “second” are used only for descriptive purposes and should not be interpreted as indicating or implying relative importance, nor should they be understood as implicitly specifying the quantity of the technical features referred to. Thus, features modified by “first” or “second” may explicitly or implicitly include one or more of such features. In the description of this application, unless otherwise specified, the term “multiple” refers to two or more.

In the description of this application, unless otherwise clearly defined and limited, the terms “install”, “connect”, and “link” should be interpreted in a broad sense. For example, a connection may be fixed or detachable, or may be integral; it may be a mechanical connection or an electrical connection; it may be a direct connection or an indirect connection implemented through an intermediate medium, including internal connections between two components. Those skilled in the art can understand the specific meanings of the above terms in the context of this application.

The implementation examples in this description are described progressively. Each implementation example focuses on differences from other examples, and identical or similar parts between the examples may be cross-referenced. For device embodiments, since they correspond to the methods disclosed, the description thereof is relatively brief, and reference may be made to the method section for relevant details.

The above description of the disclosed implementation examples enables those skilled in the art to implement or use the present disclosure. Various modifications to these embodiments will be apparent to those skilled in the art. The general principles defined herein may be applied to other embodiments without departing from the spirit or scope of the present disclosure. Accordingly, the present disclosure is not limited to the embodiments shown herein but should be accorded the broadest scope consistent with the principles and novel features disclosed in this document.

What is claimed is:

1. A synthetic method for hexaphenylbenzene-based organic small molecules having one or more of the chemical structures shown in Formula I or Formula II: 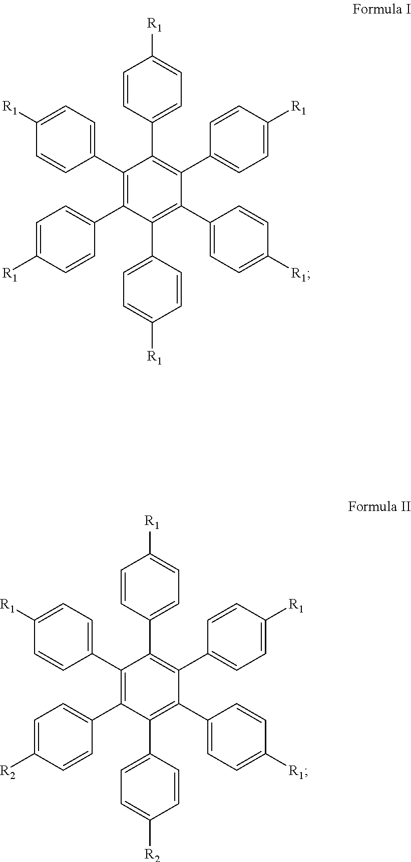
where R₁ and R₂ in Formula I or Formula II comprise:
one or a combination of H, R₃, 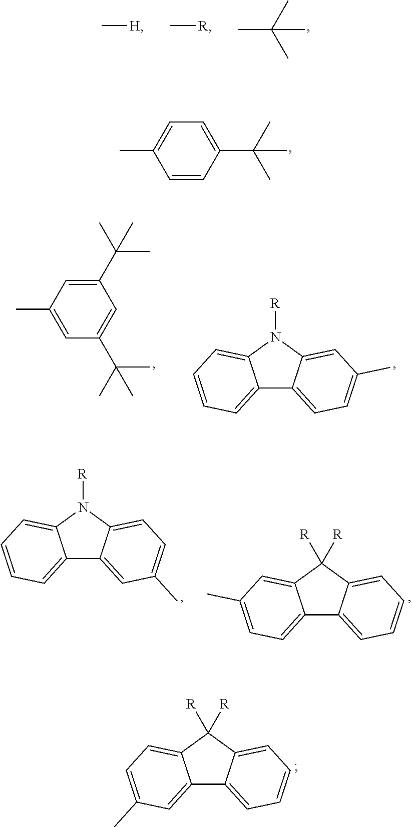
wherein for R₃ being a simple side chain of less than or equal to five carbons, a synthesis method of Formula I comprises the following steps:
Step 1) under a protection of inert gas, obtaining a first intermediate by a reaction of iodobenzene derivatives and phenylacetylene derivatives with a molar ratio of 1:(1-1.5) as raw materials, triethylamine as a solvent, cuprous iodide and bis(triphenylphosphine) palladium chloride as catalysts at room temperature for 10-15 h;
Step 2) under the protection of inert gas, using the first intermediate as the raw material, 1,4-dioxane as a solvent, and dicobalt octacarbonyl as a catalyst; performing a reaction at 100-130° C. for 8-16 h to obtain a second intermediate, namely hexaphenylbenzene-based organic small molecules in Formula I;
wherein for R3 being a complex side chain of more than five carbons, a synthesis method for Formula I comprises the following steps:
Step 1) under the protection of inert gas, using p-bis(4-bromophenyl)alkyne as raw material, 1,4-dioxane as a solvent, and dicobalt octacarbonyl as a catalyst, performing a reaction at 100-130° C. for 8-16 h to obtain a third intermediate;
Step 2) Under the protection of inert gas, using the third intermediate with a molar ratio of 1:(6-12) and boric acid or boron ester of a required side chain as raw materials, toluene/tetrahydrofuran as a solvent, tetratriphenylphosphine palladium as a catalyst, tetraethylammonium hydroxide as a base, and reacting at 70-120° C. for 12-36 h to obtain a fourth intermediate, namely hexaphenylbenzene-based organic small molecules in Formula I;
wherein a synthesis method for hexaphenylbenzene-based organic small molecules in Formula II comprises the following steps:
Step 1) under the protection of inert gas, using diphenylethanedione and 1,3-diphenylacetone or 1,2-bis(4-(tert-butyl)phenyl) ethane-1,2-dione and 1,3-bis(4-(tert-butyl)phenyl) propan-2-one with a molar ratio of 1:1 as raw materials, tert-butanol as a solvent, potassium tert-butanol as a base, and reacting at 90-110° C. for 0.5-1 h to obtain a fifth intermediate;
Step 2) under the protection of inert gas, using p-bis(4-bromophenyl)alkyne with a molar ratio of 1:2-2.5 and the boric acid or boron ester of a required side chain as raw materials, toluene as a solvent, tetratriphenylphosphine palladium as a catalyst, tetraethylammonium hydroxide as a base, and reacting at 90-110° C. for 10-16 h to obtain a sixth intermediate;
Step 3) under the protection of inert gas, using the fifth and sixth intermediates with a molar ratio of 1:1 as raw materials, diphenyl ether as a solvent, and performing a reaction at 200-260° C. for 20-24 h to obtain a seventh intermediate, namely the hexaphenylbenzene-based organic small molecules in Formula II.

2. The synthetic method for hexaphenylbenzene-based organic small molecules according to claim 1, wherein —R₃ is a long-chain alkyl or long-chain alkoxy group, and consists of the following 24 molecules:

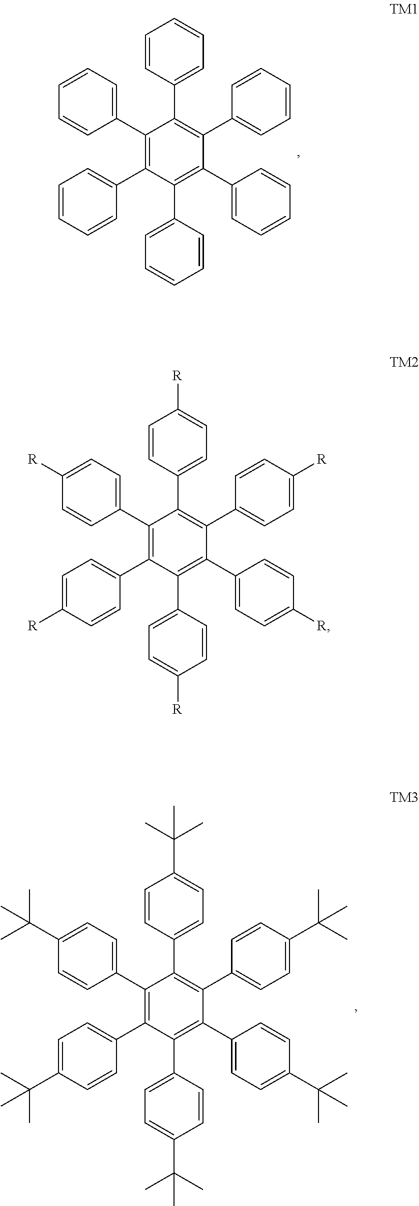

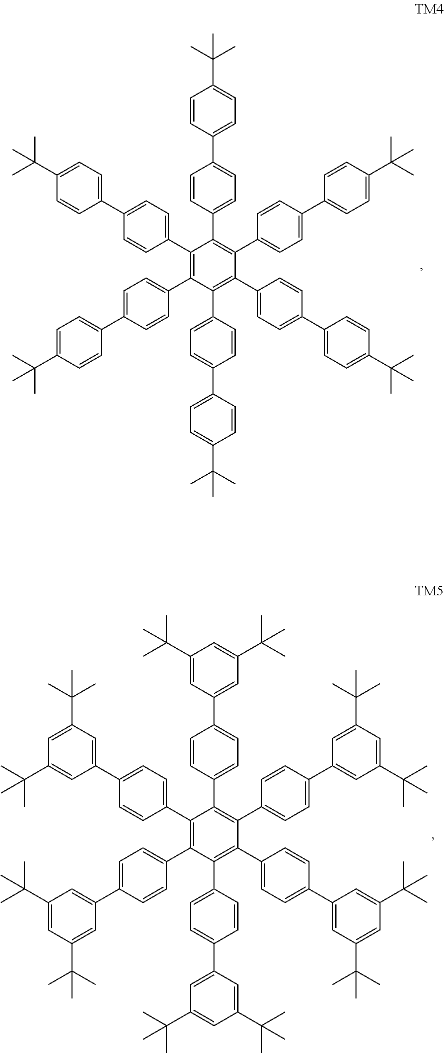

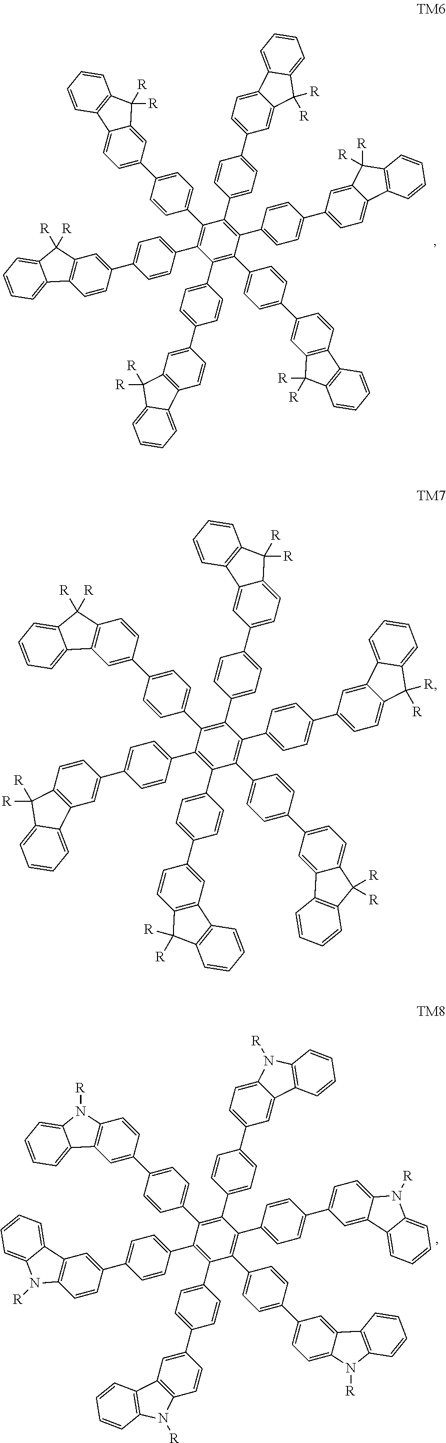

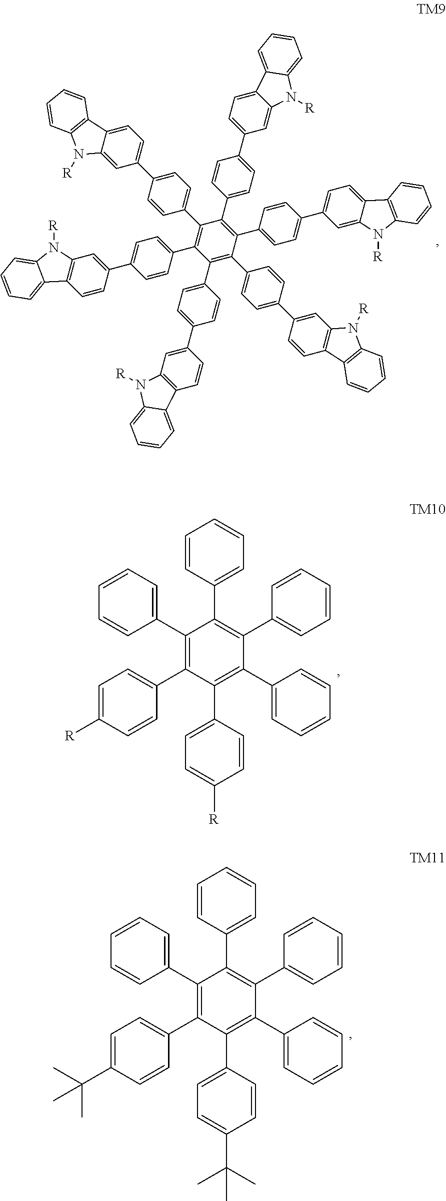

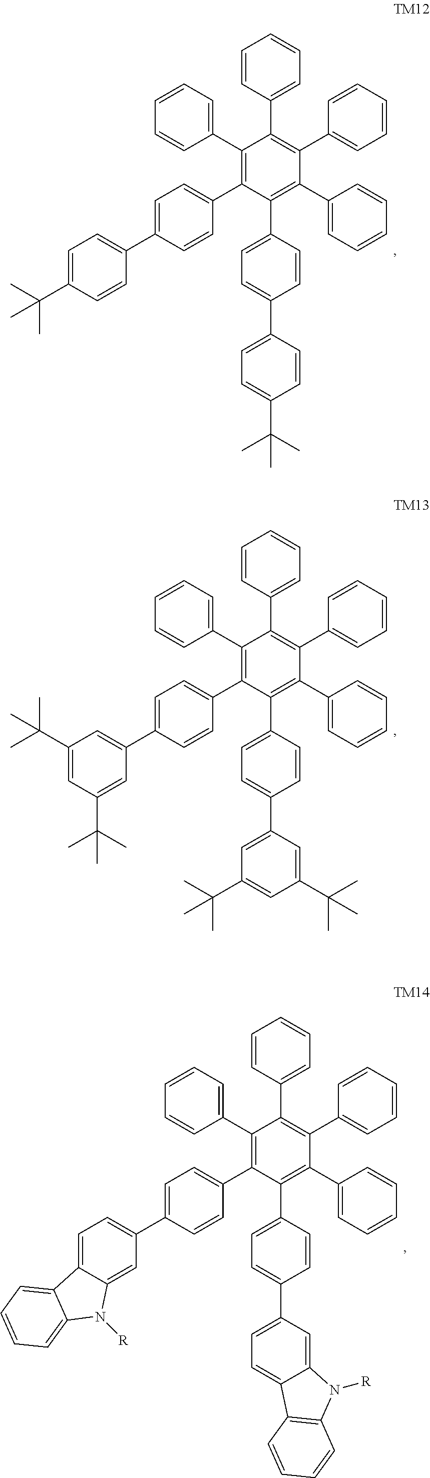

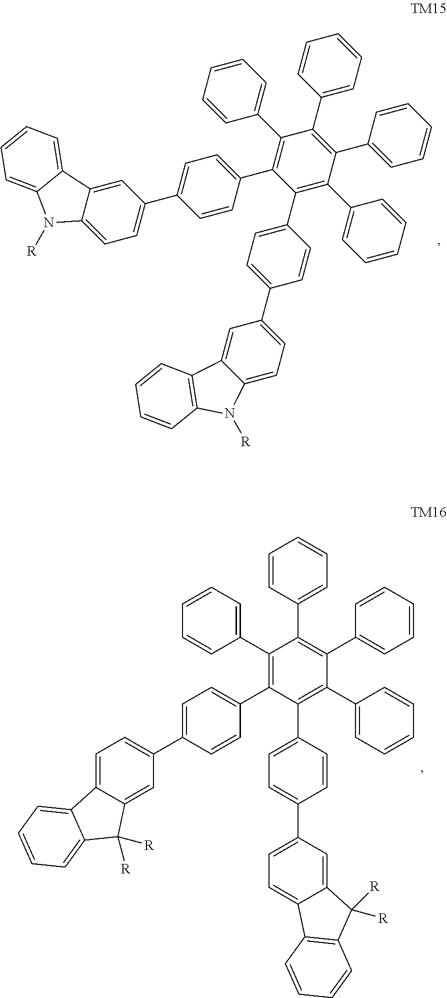

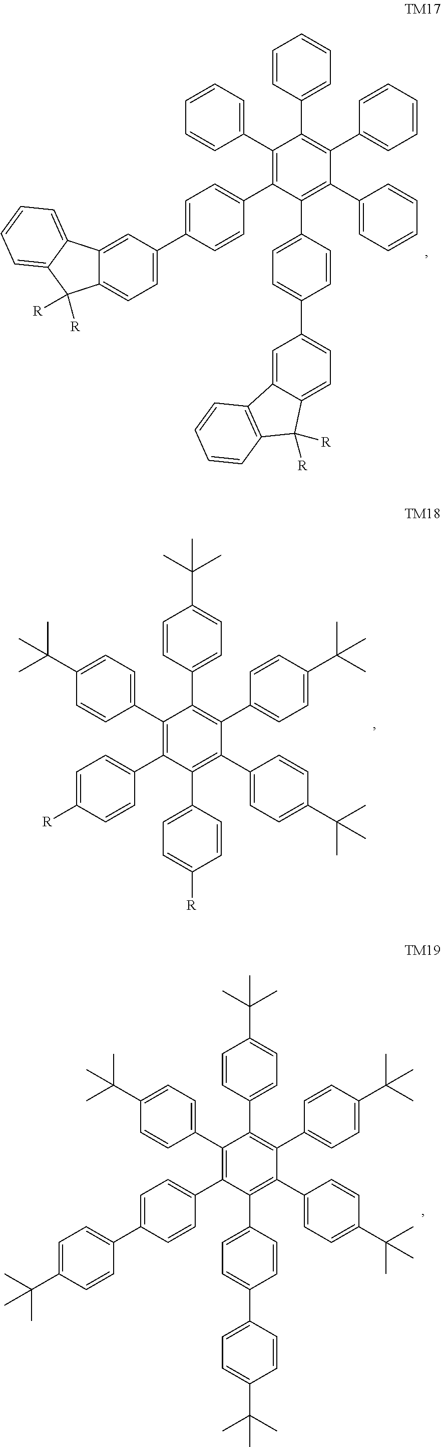

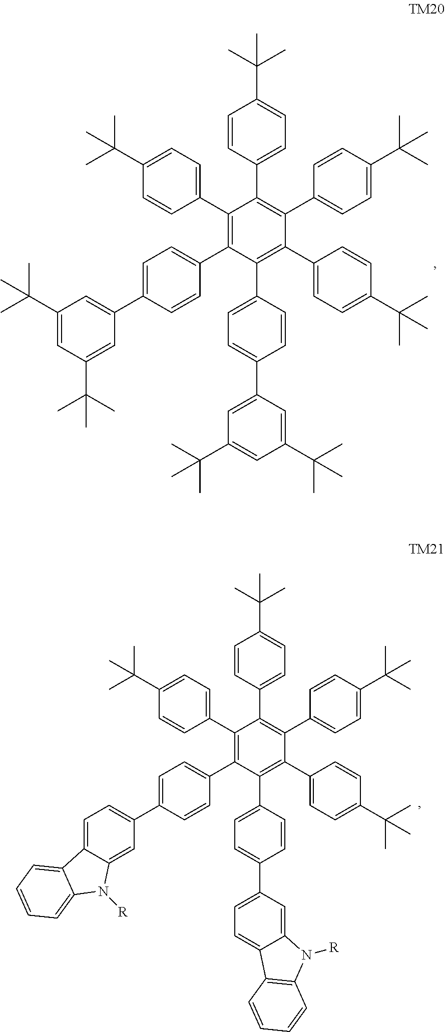

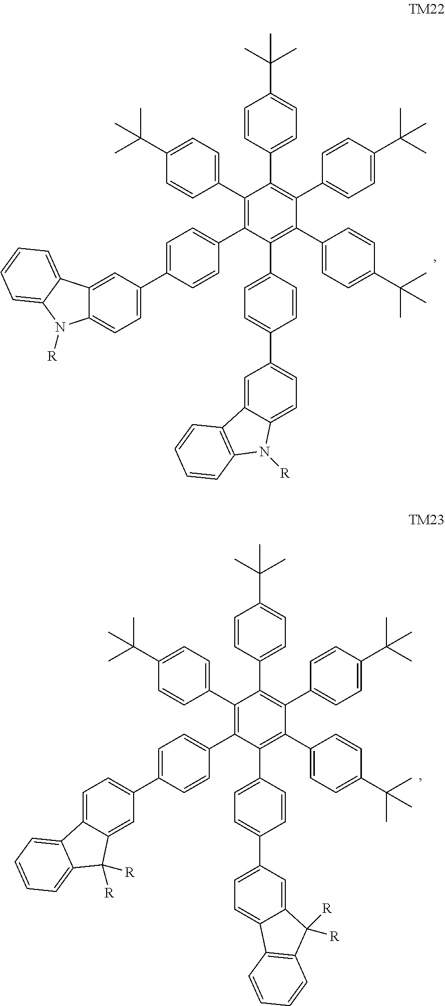

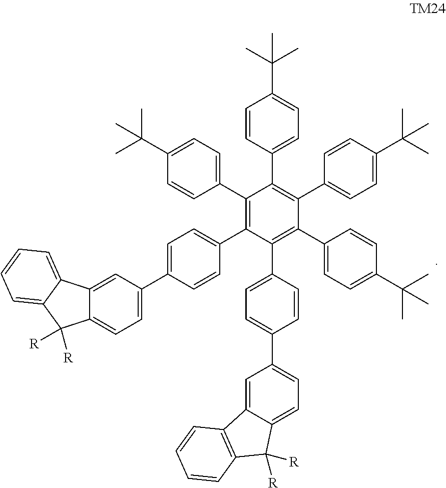

3. An electroluminescent device, comprising a cathode and an anode and a functional layer between the cathode and the anode, wherein the functional layer contains the hexaphenylbenzene-based organic small molecules according to claim 1.

4. An electroluminescent device, comprising a cathode and an anode and a functional layer between the cathode and the anode, wherein the functional layer contains the hexaphenylbenzene-based organic small molecules according to claim 2.
